(19) United States
(12) Patent Application Publication
(10) Pub. No.: US 2026/0321329 A1
(43) Pub. Date: Oct. 15, 2026

(54) SYSTEM AND DEVICE OF NON-VOLATILE MEMORY FOR IN-MEMORY COMPUTING AND OPERATION METHODS THEREOF

(71) Applicant: Infineon Technologies LLC, San Jose, CA (US)

(72) Inventors: Shivananda SHETTY, Fremont, CA (US); Long HINH, San Jose, CA (US); Vineet AGRAWAL, San Jose, CA (US); Stefano AMATO, Unterhaching (DE); Ravi KUMAR, Redwood City, CA (US); Swatilekha SAHA, Cupertino, CA (US); Vijay RAGHAVAN, Driftwood, TX (US); Bogdan GEORGESCU, Colorado Springs, CO (US); Gokul Kumar SINGARAVADIVELU, Colorado Springs, CO (US)

(73) Assignee: Infineon Technologies LLC, San Jose, CA (US)

(21) Appl. No.: 19/177,243

(22) Filed: Apr. 11, 2025

(51) Int. Cl. G11C 27/00

(52) U.S. Cl. CPC G11C 27/005

(57) ABSTRACT

Semiconductor devices and methods of operation the same are provided. The semiconductor devices may include non-volatile memory (NVM) array(s) each including in-memory computing (IMC) units arranged in rows and columns. The IMC unit includes at least two NVM cells configured to store a weight value, bit line (BL) bundles each including at least two BLs coupled to one column of the IMC units to provide a BL voltage set representing an input value. The IMC units of the column each provides a cell current output varies according to the weight value and the BL voltage set coupled thereto, a plurality of source lines (SLs) and each SL coupled with the cell current outputs of one row of the IMC units, wherein positive cell current outputs are canceled, at least partially, by negative cell current outputs of the one row of the IMC units. Other embodiments are also described.

### CROSS-REFERENCE TO RELATED APPLICATIONS

None.

### TECHNICAL FIELD

This disclosure relates generally to semiconductor devices and more particularly pertaining to non-volatile memory devices and system for in-memory computing (IMC) and/or multiply-accumulate (MAC) applications, and methods of operation the same.

### BACKGROUND

Non-volatile memories (NVM) are widely used for storing data in computer systems, and typically include a memory array with a large number of memory cells arranged in rows and columns. There are demands to use NVM technology, such as semiconductor-oxide-nitride-oxide-semiconductor (SONOS), for analog memory and processing as they can be configured with multiple (e.g. more than two) threshold voltage (VT) and cell or drain current (Ic or I_{D}) levels with achievably high precision. SONOS or other NVM cells deliver low latency, power, and noise operations that are desirable for analog processing, including at edge inference computations, such as neuromorphic computing in artificial intelligence (AI) applications.

AI or machine learning may use algorithms to find patterns in data and use a model that recognizes those patterns to make predictions on any new data or patterns. At the heart of AI applications or machine learning, there is the multiply-accumulate (MAC) or dot product operation, wherein it may take two numbers (input values and weight values), multiplies them together, and add the results to an accumulator. Such MAC operations involve the application of weight values to input values (which may correspond to a multiply operation) and the summation of the resulting products (which may correspond to an accumulation operation). Circuits that can execute MAC operations can be desirable additions to many systems. One such system can be an artificial neural network (ANN). A MAC device/system that adopts a conventional digital Von-Neumann architecture, may create major bottleneck issues between GPUs that process the MAC computation and memory that only stores data (weight values, input values, output values, etc.) due to the frequent accesses of the memory.

It is, therefore, one object of the present disclosure to propose inferencing devices or systems using NVM technologies that have the capability of storing analog input values and/or weight values as well as executing MAC operations.

### BRIEF DESCRIPTION OF THE DRAWINGS

The present patent disclosure will be understood more fully from the detailed description that follows and from the accompanying drawings and the appended claims provided below, where:

FIG. 1 a schematic diagram of an embodiment of a neural network (NN);

FIG. 2A is a diagram showing conventional matrix operations giving rise to multiply-accumulate (MAC) operations;

FIG. 2B is a diagram of a conventional cross point array for generating MAC results;

FIG. 3 is a schematic diagram of an in-memory computing (IMC) device according to an embodiment of the present disclosure;

FIGS. 4A to 4E are representative diagrams showing nonvolatile memory (NVM) cells that can be included in IMC arrays according to embodiments of the present disclosure;

FIG. 5 is a side cross sectional view of an NVM cell that may be included in embodiments of the present disclosure;

FIG. 6 is a top plan view of a row of NVM cells that can be included in embodiments of the present disclosure;

FIG. 7A is a block diagram showing an IMC array adopting a one-cell per weight configuration according to embodiments of the present disclosure;

FIG. 7B is a representative block diagram showing an IMC device using IMC arrays in FIG. 7A according to embodiments of the present disclosure;

FIG. 8A is a representative block diagram showing an IMC device adopting a two-cell per weight configuration according to embodiments of the present disclosure;

FIGS. 8B and 8C are block diagrams showing a portion of a two-cell per weight IMC array according to embodiments of the present disclosure;

FIG. 9 is a representative block diagram showing an IMC device adopting a two-cell per weight configuration according to embodiments of the present disclosure;

FIG. 10 is a representative block diagram showing an IMC unit adopting a four-cell per weight configuration according to embodiments of the present disclosure;

FIG. 11 is a representative block diagram showing an IMC device adopting a four-cell per weight configuration according to embodiments of the present disclosure;

FIG. 12A is a flow diagram of a method of operation according to an embodiment of the present disclosure;

FIG. 12B is a flow diagram of another method of operation according to an embodiment of the present disclosure;

FIG. 13 is a flow diagram of a further method of operation according to an embodiment of the present disclosure; and

FIG. 14 is a representative block diagram of another embodiment of an IMC device having multiple IMC arrays according to the present disclosure.

The features and advantages of embodiments of the present invention will become more apparent from the detailed description set forth below when taken in conjunction with the drawings. In the drawings, like reference numbers generally indicate identical, functionally similar, and/or structurally similar elements.

### DETAILED DESCRIPTION

This specification discloses one or more embodiments that incorporate the features of this invention. The disclosed embodiment(s) merely exemplify the present invention. The scope of the present invention is not limited to the disclosed embodiment(s). The present invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Before describing the various embodiments in more detail, further explanation shall be given regarding certain terms that may be used throughout the descriptions. Unless specifically stated otherwise, as apparent from the following discussions, it is appreciated that throughout the specification discussions utilizing terms such as “processing”, “computing”, “calculating”, “determining”, “inferencing”, or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

### Summary of Subject Matter

According to one embodiment of a semiconductor device, the semiconductor device may include at least one non-volatile memory (NVM) array, and each NVM array has in-memory computing (IMC) units arranged in rows and columns. Each IMC unit includes at least two NVM cells configured to store a weight value. The semiconductor device may also include a plurality of bit line (BL) bundles, each BL bundle including at least two BLs coupled to one column of the IMC units to provide a BL voltage set representing an input value, wherein the IMC units of the one column each provides a cell current output varies according to the weight value stored therein and the BL voltage set coupled thereto, and a plurality of source lines (SLs), each SL coupled with the cell current outputs of one row of the IMC units, in which the positive cell current outputs are canceled, at least partially, by the negative cell current outputs of each row of the IMC units.

In one embodiment, the semiconductor device in which the cell current outputs each represents a function of each input value and a corresponding weight value stored by the IMC units of the one row, and cumulative cell current outputs along each SL represents a multiply-accumulate (MAC) result.

In one embodiment, in which the semiconductor device may further include a plurality of word lines (WLs), each WL coupled to a corresponding row of the IMC units, and each configured to select the IMC units of the corresponding row for an operation including a multiply-accumulate (MAC) operation.

In one embodiment, the semiconductor in which the weight values are analog weights of a multiply-accumulate (MAC) operation, and each NVM cell includes a multi-level SONOS based memory transistor having a threshold voltage representing the weight value stored therein.

In one embodiment, the semiconductor device in which each IMC unit includes two NVM cells and the weight value stored therein has one of zero, positive, or negative value. In one embodiment, a positive weight value is stored in a first NVM cell of the each IMC unit, a negative weight value is stored in a second NVM cell, in which the first and second NVM cells are coupled to a same SL and first and second BLs of a same BL bundle, respectively, and a zero weight value is stored both in the first and second NVM cells.

In one embodiment, the semiconductor device in which the BL voltage set coupled to the each IMC unit includes a positive BL voltage, in response to the input value being positive, is provided to the first BL, and a negative BL voltage, in response to the input value being positive, is provided to the second BL.

In one embodiment, the semiconductor device in which the BL voltage set coupled to the each IMC unit includes a negative BL voltage, in response to the input value being negative, is provided to the first BL, and a positive BL voltage, in response to the input value being negative, is provided to the second BL.

In another embodiment, the semiconductor device in which each IMC unit includes four NVM cells arranged in two adjacent NVM cell columns and the weight value stored therein has one of zero, positive, or negative value. In one embodiment, a positive weight value is each stored in first and fourth NVM cells coupled to first and fourth BLs in a same BL bundle respectively, a negative weight value is each stored in second and third NVM cells coupled to second and third BL of the same BL bundle respectively, wherein the first and second NVM cells and the third and fourth NVM cells are each arranged in the same NVM cell column respectively, and a zero weight value is stored in the first, second, third, and fourth NVM cells.

In one embodiment, the semiconductor device in which the BL voltage set coupled to the IMC unit includes a positive BL voltage, in response to the input value being positive, is provided to the first BL, a negative BL voltage, in response to the input value being positive, is provided to the second BL, and a zero BL voltage, in response to the input value being positive, is provided to the third and fourth BLs.

In one embodiment, the semiconductor device in which the BL voltage set coupled to the IMC unit includes a positive BL voltage, in response to the input value being negative, is provided to the third BL, a negative BL voltage, in response to the input value being negative, is provided to the fourth BL, and a zero BL voltage, in response to the input value being negative, is provided to the first and second BLs.

According to an embodiment of an inferencing device, the inferencing device may include at least one non-volatile memory (NVM) array, wherein each NVM array includes in-memory computing (IMC) units arranged in rows and columns, wherein the IMC unit each includes at least two NVM cells to collectively store a weight value, a bit line (BL) driver coupled to the each NVM array, wherein the BL driver receives input value sets of multiply-accumulate (MAC) operations and provides BL voltage sets accordingly, a plurality of bit line (BL) bundles coupled to the BL driver, each BL bundle including at least two BLs coupled to one column of the IMC units to provide the BL voltage set from the BL driver, wherein the IMC units of the one column each provides a cell current output varies according to the weight value stored therein and the BL voltage set coupled thereto, a plurality of source lines (SLs), each SL coupled with the cell current outputs of one row of the IMC units, wherein positive cell current outputs of the one row of the IMC units are canceled, at least partially, by negative cell current outputs along the each SL, and a processing element coupled to the plurality of SLs to receive cumulative cell current outputs of each SL, the processing element is configured to generate a MAC result based on cumulative cell current outputs of the each SL.

In one embodiment, the inferencing device may include one NVM array, wherein each IMC unit includes four NVM cells arranged in two adjacent NVM cell columns and the weight value stored therein has one of zero, positive, or negative value. In one embodiment, a positive weight value is each stored in first and fourth NVM cells coupled to first and fourth BLs in a same BL bundle respectively, a negative weight value is each stored in second and third NVM cells coupled to second and third BL of the same BL bundle respectively, wherein the first and second NVM cells and the third and fourth NVM cells are each arranged in a same NVM cell column, respectively, and a zero weight value is stored in the first, second, third, and fourth NVM cells.

In one embodiment, the inferencing device in which the BL voltage set coupled to the IMC unit includes a positive BL voltage, in response to the input value being positive, is provided to the first BL, a negative BL voltage, in response to the input value being positive, is provided to the second BL, and a zero BL voltage, in response to the input value being positive, is provided to the third and fourth BLs.

In one embodiment, the inferencing device in which the BL voltage set coupled to the IMC unit may include a positive BL voltage, in response to the input value being negative, is provided to the third BL, a negative BL voltage, in response to the input value being negative, is provided to the fourth BL, and a zero BL voltage, in response to the input value being negative, is provided to the first and second BLs.

In one embodiment, the inferencing device in which the BL driver is disposed in the middle of the one NVM array and provides same BL voltage sets to two halves of the plurality of BL bundles coupled thereto.

In one embodiment, the inferencing device in which the input value sets include digital values in binary bits, and wherein the MAC operations are performed bit by bit until last binary bits of the input value sets are processed.

In one embodiment, the inferencing device in which one row of IMC units includes a kernel, wherein the kernel is configured to store a set of weight values to generate the MAC operations with the input value sets.

In one embodiment, the inferencing device in which the processing element further includes scaling circuitry configured to scale the MAC result of each binary bit of the input value sets according to significance of the each binary bit, multiplexers circuitry configured to couple to a different set of SLs, integrator circuitry configured to integrate scaled MAC results of the binary bits of the input value sets to generate an overall MAC result, and analog-digital converter (ADC) circuitry configured to covert the overall MAC result into a digital output of the inferencing device.

According to one embodiment of a method of operating an inferencing device, the method may include the steps of storing weight values in in-memory computing (IMC) units each including at least two nonvolatile memory (NVM) cells of an NVM cell array of the inferencing device, the NVM cell array having rows and columns, wherein one row and one column of the IMC units are coupled to a source line and a bit line bundle respectively, wherein weight values can vary between no less than three different values and are one of positive values, negative values, or zero, for at least one row, generating a multiply-accumulate (MAC) result for the row by applying bit line voltage sets representing input values on bit line bundles wherein input values are one of positive values, negative values, or zero, the MAC result comprising a summation of an analog current that is a function of each input value and a corresponding weight value stored by the IMC units of the row, wherein positive analog current is cancelled at least partially by negative analog current provided by IMC units of the row, and by operation of at least one multiplexer, connecting one of a plurality of the rows to an analog-to-digital converter (ADC) circuit to convert the summation of the analog current of the row into a digital MAC value.

In one embodiment, the method of operating the inferencing device in which each IMC unit include four NVM cells, the method may further include the steps of generating, by a bit line driver, the bit line voltage sets each including four individual bit line voltages, each of the bit line voltages provided to one of the four NVM cells respectively, wherein the bit line voltage set causes only one of the four NVM cells of the each IMC unit to provide the analog current from the IMC unit.

### DESCRIPTION OF EMBODIMENTS

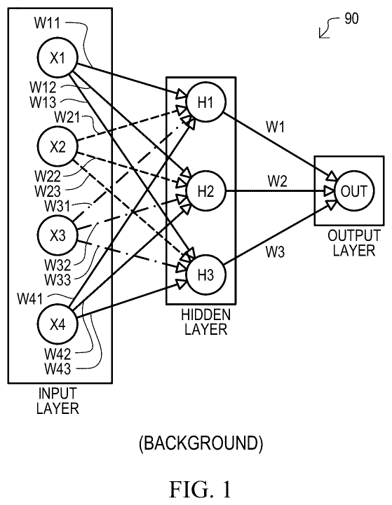

FIG. 1 a schematic diagram of an embodiment of a neural network (NN) or an artificial neural network (ANN). Artificial Intelligence (AI) may be defined as the ability of a machine to perform cognitive functions executed by a human brain, such has reasoning, perception, and learning. Machine learning may use algorithms to find patterns in data and use a model that recognizes those patterns to make predictions on any new data or patterns. At the heart of AI applications or machine learning, there is the multiply-accumulate calculation (MAC) or dot product operation, wherein it may take two numbers (input values or multiplicand and weight values), multiplies them together, and add the results to an accumulator. ANN 90 may include an input layer, an output layer, and one or more hidden layers. Hidden layers and the output layer can include one or more artificial neurons. In the example shown, the hidden layer includes three neurons (H1, H2, H3) and the output layer includes one neuron (OUT).

A neuron can execute MAC operations on input values to generate an output value, which can be passed on to a next layer, or as an output for the ANN. Neurons can also include additional operations, such as activation functions and/or filtering/pooling. Such MAC operations involve the application of weight values to input values (which can correspond to a multiply operation) and the summation of the resulting products (which can correspond to an accumulation operation). In a training operation, ANN 90 can have an initial set of weight values, which can be revised as training input data sets are applied and resulting output values are generated and evaluated. Once trained, weight value can be essentially set, and an ANN 90 can execute inference operations, generating predicted output values from new input data sets.

Referring to FIG. 1, weight values for hidden layer neurons are shown as Wi,j, where i=1-4 and j=1-3. Thus, neuron H1 will multiply value X1 by weight W11, X2 by weight W21, X3 by weight W31, and X4 by weight W41. Such products will be summed (and possibly subject to other operations), and the result output from neuron H1 and provided as an input to neuron OUT. Neuron OUT will multiply the output from H1 by weight W1. The operation of the other neurons of FIG. 1 is understood from this description.

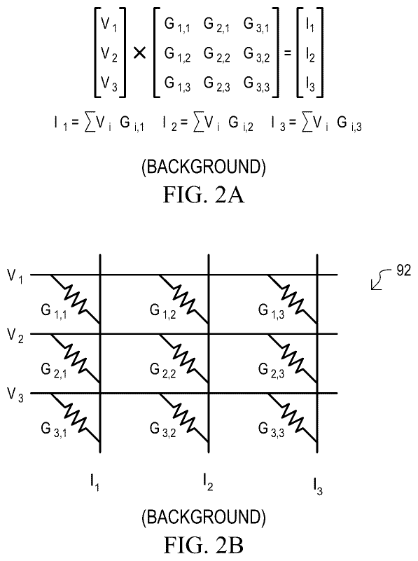

In many applications, neuron operations can be represented by matrix multiplication. FIG. 2A shows an example of such matrix multiplication. Vector V (with components Vi (i=1-3)) can correspond to input values, operation vector G (with components (Gi,j) (j=1-3)) can correspond to weight values, and vector Ii, can correspond to resulting output values.

One conventional way of implementing the vector operation shown in FIG. 2A can be with a crossbar memory array. FIG. 2B shows a conventional crossbar memory array 92. Crossbar memory array 92 can include memory elements (Gi,j), represented by resistances as an example, arranged into rows and columns. Memory elements of a same row can be connected to a same word line, while memory elements of a same column can be connected to a same bit line. For example, memory elements G1,1, G1,2 and G1,3 can be connected to a same word line (which receives voltage V1). Columns of crossbar memory array 92 can be connected to a same bit line. For example, memory elements G1,1, G2,1 and G3,1 can be connected to a same bit line (which can provide current I1).

In operation, word lines can be driven with input value voltages (V1, V2, V3), resulting in the generation of currents on bit lines, which can represent a MAC result. For example, if memory element weights (Gi,j) are a conductance, a current I1 can be the summation of Vi*Gi,1. The weight terms for a given summation operation can be considered a “kernel”. FIG. 2B thus shows three column-wise kernels: Gi,1; Gi,2 and Gi,3.

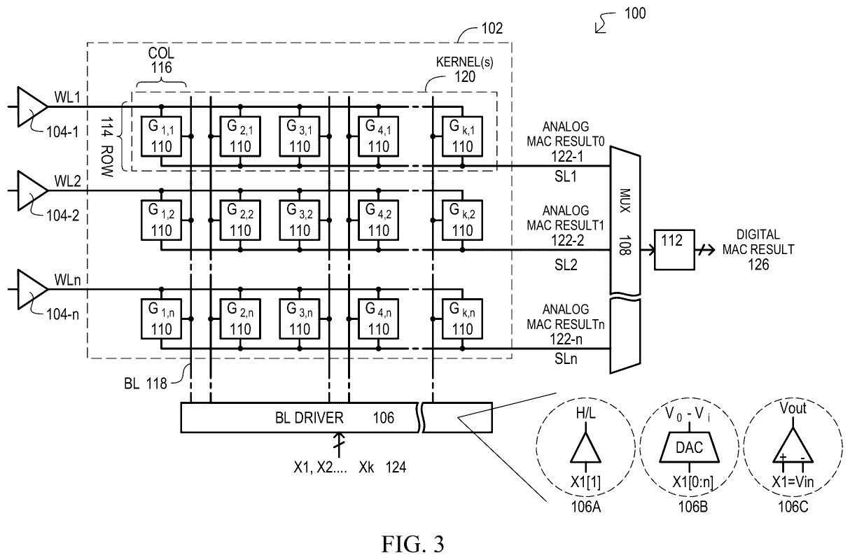

FIG. 3 is a representative block diagram of IMC or inferencing device 100 according to an embodiment of the present disclosure. An IMC device 100 may include a nonvolatile memory (NVM) cell array 102, word line drivers 104-1 to -n, bit line driver 106, source line multiplexer (MUX) section 108, and integrator and ADC section 112. NVM cell array 102 can include NVM cells 110 arranged into n*rows (one shown as 114) and k*columns (one shown as 116), making it an k*n array. NVM cells 110 of a same column can be connected to a same bit line (one shown as 118). NVM cells 110 of a same row can be connected to a same word line WL1-WLn (or set of word lines) and same source line SL1-SLn. Unlike conventional approaches, source lines (SL1-SLn) are not commonly connected, but rather separate and receive individual inputs from one another. In one embodiment, NVM cells 110 may include silicon-oxide-nitride-oxide-silicon (SONOS) based charge-trapping memory cells capable of being programmed and retaining charges to represent multiple (more than two) states or levels. In other embodiments, NVM cells 110 may be other multi-level memory cells, such as floating gate, R-RAM, M-RAM, etc. In FIG. 3, rows are shown in a horizontal orientation and columns in a vertical orientation as an example. One having ordinary skill in the art would understand orientations of rows and column may be interchangeable according to the device design and requirement.

Referring to FIG. 3, NVM cells 110 can be programmed to a predetermined multi-level current or voltage (e.g., drain current (Id) or cell current (Ic) or threshold voltage (Vt)) to the corresponding source line (SL1-SLn) when selected. Such current or voltage is represented by Gi,j, where i=1 to k, and j=1 to n. In some embodiments, NVM cells 110 can be programmed to store sets of multiplier terms (e.g., kernels 120) for MAC operations. However, in contrast to conventional approaches, such sets (one represented by 120) can be stored in a row-wise fashion along WLs and not a column-wise fashion along BLs. According to embodiments, NVM cells 110 can be programmed between at least three different states or analog levels, to provide or represent different analog weight values.

Word line drivers (104-1 to -n) can drive one or more types of word lines for each row 114 to select the NVM cells 110 of the row. In some embodiments, such as in a two-transistor (2T) configuration or 1.5T (split gate) configuration, there can be more than one word lines per row 114 (e.g., a select gate word line and control gate word line), and such different word lines can be driven separately according to mode of operation. However, in other embodiments there can be one word line per row 114. Bit line driver 106 can drive bit lines 118 according to input (e.g., multiplicand) values (X1, X2 . . . , Xk) 124. Different bit lines can represent or receive different input terms. In some embodiments, bit lines 118 can be driven between two different voltages (i.e., input terms can be digital or binary values). In other embodiments, bit lines 118 can be driven between more than two different states or driven to an analog value. Accordingly, a bit line driver 106 can include any of: digital driver circuits 106A, multi-bit driver circuits 106B or analog driver circuits 106C. Digital driver circuits 106A can drive a bit line between two voltage levels in response to a binary input value X1 [1]. Multi-bit driver circuit 106B can drive a bit line between three or more levels. In some embodiments, a bit line driver 106B can include a digital-to-analog converter (DAC), that can generate different output voltages (V0 to Vi) in response to a multi-bit input value X1[0:n] (where n>1). Analog driver circuits 106C can drive a bit line to an analog voltage Vout in response to an analog input voltage Vin, which may or may not be the same as Vout.

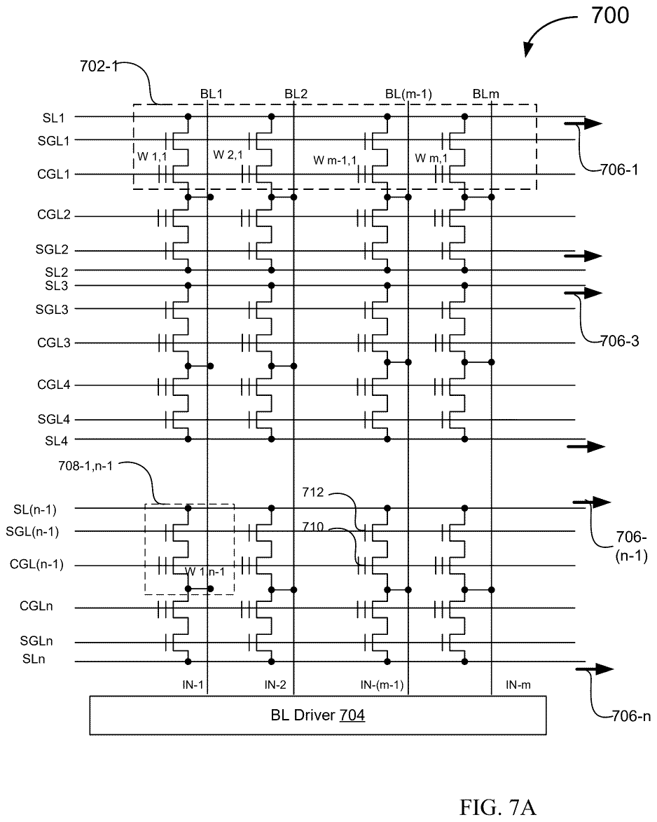

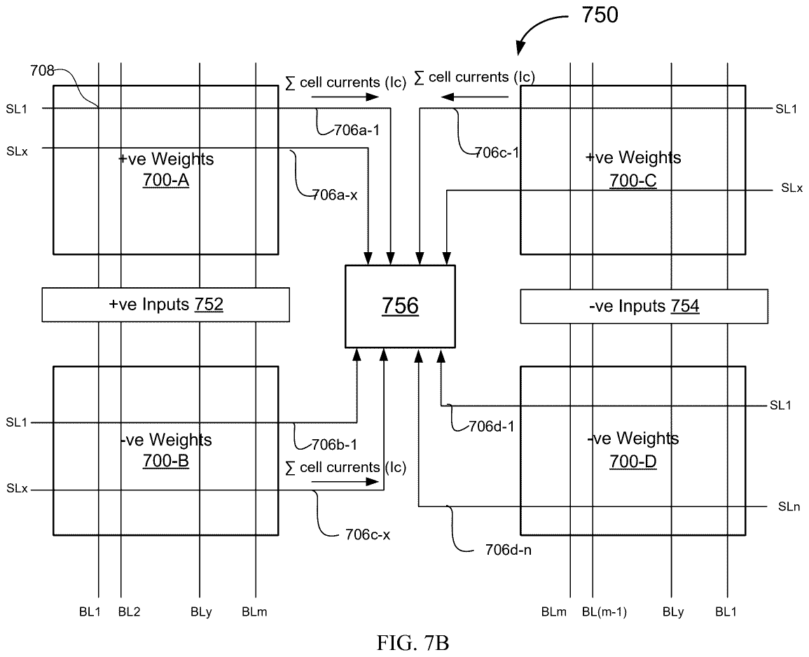

MUX section 108 can include one or more MUXs for selectively connecting source lines (SL1 to SLn) to integrator and ADC section 112. Integrator and ADC section 112 may perform arithmetic operation a voltage or current on selected source line (SL1 to SLn). Subsequently, integrator and ADC section 112 can convert the result of such arithmetic operation on a selected source line (SL1 to SLn) into a digital value. In embodiments in which multiple NVM cell arrays 102 are employed, as later shown in FIGS. 7B, 9, and 11, voltage or current output from the NVM cell arrays 102 may be added, subtracted, or subjected to other arithmetic calculations before being converted into digital values, which will be further explained in later sections of this document.

Having described the general sections of IMC device 100, MAC operations will now be described. Kernels (e.g., 120) that each represents a set of weights can be stored in rows along WLs of NVM cell array 102. In embodiments, kernels 120 may take an entire row or a portion of the row. BL voltages representing input values or multiplicand 124 can be driven on bit lines 118 by BL driver 106. Row drivers (104-1 to -n) can drive a word line (WL1 to n) to select a row or rows for MAC operations. In response, a current path can be enabled through the NVM cells 110 of the selected row, between each bit line 118 and the source line (SL1 to SLn) for the row.

Such cell currents are thus summed or accumulated on the source line as an analog MAC result (122-1 to -n).

MUX section 108 can connect the source line (SL1 to SLn) to the ADC section 112. The ADC section 122 can convert the selected analog MAC result (122-1 to -n) into a digital MAC result 126. Such an operation can be repeated to generate MAC results (122-1 to -n) for each row in response to a same set of input values on bit lines 118. IMC device 100 can have various features that differ from conventional approaches. According to embodiments, NVM cell array 102 can store kernels in rows along SLs and WLs, as opposed to columns along BLs. Input values can be applied via bit lines 118, rather than word lines. Further, NVM cell array 102 can have source lines (SL1 to SLn) dedicated to each row, rather than unified source lines as in the conventional case. MAC results can be summed on or along source lines, and not bit lines. Similarly, rows (e.g., source lines) can be multiplexed to ADC circuits as opposed to columns (e.g., bit lines 118).

In some embodiments, bit line driver 106 can provide inputs for neurons and kernels 120 can be weight values for such neuron inputs. Each analog MAC result (122-1 to -n) can correspond to a different neuron in response to the same input value set (e.g., neurons of a same hidden layer), as previously explained in FIG. 1.

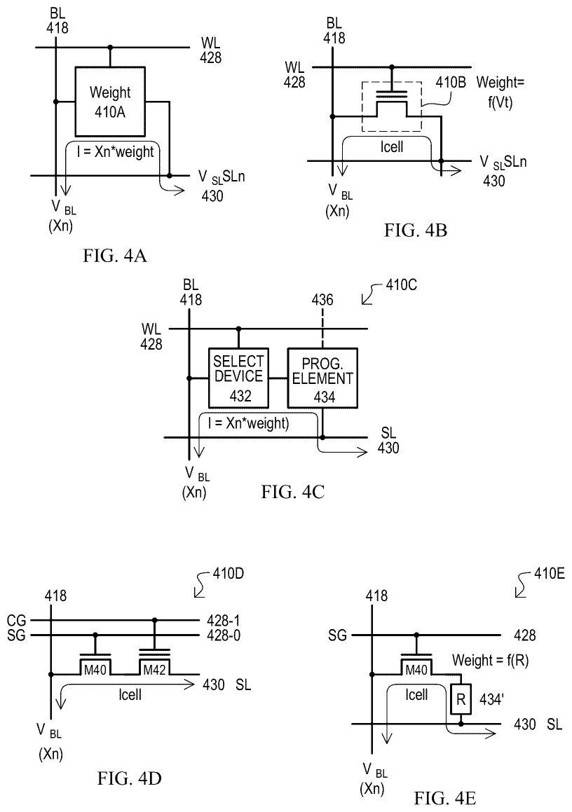

Embodiments can include memory cells of any suitable type that can be programmed between more than two distinctive levels or states, where each different state can provide a different current or voltage response. FIGS. 4A to 4E are diagram showing examples of NVM cells that can be included in embodiments of the present disclosure. FIG. 4A is a block diagram of a memory cell 410A that can be included in NVM

cell arrays 102 according to embodiments. A memory cell 410A can be connected to a bit line 418, a word line 428 and a source line 430. Memory cell 410A can be programmed with an analog weight value, which can dictate the magnitude of a current flow through the memory cell 410A. In response to a voltage on word line 428, a conductive path can be enabled or disabled between bit line 418 and source line 430. Bit line 418 can be at a voltage V_{BL} which can vary according to an input value Xn. Source line 430 can be at a source line potential V_{SL}. A current (I) flowing through the memory cell 410A can vary according to the stored weight value, and in some embodiments I=Xn*Weight or I is proportional to Xn*Weight. A direction of current I can vary according to the values of V_{BL} and V_{SL}.

FIG. 4B is a schematic diagram of one-transistor (1T) cell 410B that can be included in NVM cell arrays 102 according to embodiments. A 1T cell 410B can have an IGFET structure with a threshold voltage (Vt) programmable between no fewer than three distinctive levels or values. A threshold voltage (Vt) can be established with any suitable structure, including a floating gate or other charge trapping mechanism, such as a SONOS type device. A SONOS type device can include silicon or semiconductor substrate, ONO gate dielectric, and silicon or semiconductor (e.g., polysilicon gate), however a SONOS type device can also be subject to variation in building materials, gate types, substrate types, and gate dielectric structures, as practiced by ordinary skill in the art. A 1T cell 410B can be selected as described for the cell of FIG. 3. A resulting cell current Ic can vary according to the programmed Vt.

FIG. 4C shows a two-device memory cell 410C that can be included in NVM cell arrays 102 according to embodiments. Memory cell 410C can include an access or select device 432 and a programmable element 434. In response to a voltage on a word line 428, select device 432 can enable a conductive path between bit line 418 and programmable element 434. A programmable element 434 can be programmed between three or more weight values. In some embodiments, programmable element 434 can be connected to one or more other nodes (shown as 436) to enable the programmable element and/or to program a weight value into programmable element. A resulting current can vary according to the weight value programmed in the programmable element. A programmable element can be a two-terminal device or a three-terminal device. In one alternative embodiment, positions of select device 432 and programmable element 434 may be swapped such that select device 432 is coupled to SL 430 whereas programmable element 434 to BL 418 receiving V_{BL} (i.e. input value Xn). It would be the understanding that positions of access device 432 and programmable element 434 are interchangeable to enable the conductive path between BL 418 and SL 430.

FIG. 4D shows a two-transistor (2T) memory cell 410D that can be included in NVM cell arrays 102 according to embodiments. Memory cell 410D can include a select transistor M40 and a programmable transistor M42. Select transistor M40 can be enabled by a voltage on a select gate (SG) word line 428-0 to provide a current path between bit line 418 programmable transistor M42. Programmable transistor M42 can have a programmable Vt as described herein and equivalents. In some embodiments, programmable transistor can be a SONOS type charge trapping device. In some embodiments, in a current generating (e.g., MAC) operation, a control gate 428-1 can be biased to generate the desired weighted cell current (Ic). While FIG. 4D shows transistors of n-type conductivity, alternate embodiments can include transistors of p-type conductivity, as well as enhancement or depletion mode transistors. In an alternative embodiment, similar to FIG. 4C, positions of select transistor M40 and programmable transistor M42 may be swapped such that select transistor M40 is coupled to SL 430 whereas programmable transistor M42 to BL 418 receiving V_{BL} (i.e. input value Xn).

FIG. 4E shows another 1T memory cell 410E that can be included in NVM cell arrays 102 according to embodiments. Memory cell 410E can include a select transistor M40 and a programmable element 434′. Select transistor M40 can be enabled by a voltage on a select gate (SG) word line 428 to provide a current path between bit line 418 programmable element 434′. Programmable element 434′ can be programmed between three or more resistance states. Programmable element 434′ can take any suitable form, including but not limited: to a ferroelectric random access memory (FRAM) element, magnetoresistive RAM (MRAM) elements, phase change RAM (PCM) elements, or resistive RAM (RRAM) elements.

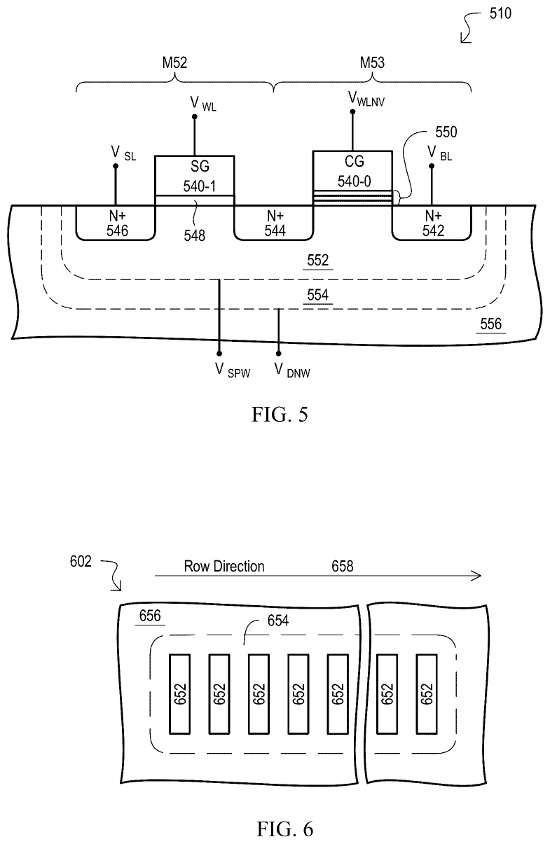

FIG. 5 is a cross-sectional diagram of a memory cell 510 that can be included in embodiments. A memory cell 510, similar to two-transistor (2T) memory cell 410D in FIG. 4D, can include a select transistor M52 and a programmable transistor M53 formed with a substrate 556. Select transistor M52 can have a drain 546 connected to receive a bit line voltage V_{BL}, a select gate (SG) connected to, or formed as part of a select word line 540-1, and a diffusion 544 serving as a source. A select gate SG can be formed over a gate dielectric 548. Select gate (SG) can be driven to a voltage VWL, which can vary according to operations.

Programmable transistor M53 can have a drain from diffusion 544, a control gate (CG) connected to, or formed as part of a program word line 540-0, and a source connected to, or formed as part of a source line 546. A control gate (CG) can be formed over a charge storage gate dielectric 550, which in some embodiments can include a layer of silicon nitride formed between layers of silicon oxide (i.e., ONO). Programmable transistor M53 can have a SONOS type structure. A control gate (CG) can be driven to a voltage V_{WLNV}, which can vary according to operation. In some embodiments, a magnitude and/or number of pulses for V_{WLNV}, can be used to program a weight value into programmable transistor. Source line 546 can be driven to a voltage V_{SL}, which can also vary according to operation.

In the embodiment shown, select and programmable transistors M52/M53 can be n-channel devices. However, alternate embodiments can include different conductivity type transistors. Select and programmable transistors (M52/M53) can have insulated gate field effect transistor type structures. However, alternate embodiments can have different transistor structure types.

Select and programmable transistors M52/M53 can be formed in a first region 552, which in some embodiments can be a well doped to an opposite conductivity type to source/drains of M52/M53 (e.g., p-type well). According to embodiments, first region 552 can be driven to a voltage VSPW, which can vary according to operation. In the embodiment shown, first region 552 may itself be contained in a second region 554. In some embodiments, a second region 554 can be a deep well doped to an opposite conductivity type to first region 552. Such an arrangement can enable first region 552 to be biased to voltages outside of a power supply voltage for a device. For example, first region 552 can be driven to a negative voltage to erase and/or program programmable transistor M53 to store a weight value.

FIG. 6 is a top plan view of a portion of an NVM cell array 602 that can be included in embodiments. FIG. 6 shows memory cell regions 652 formed in a substrate 656. Memory cell regions 652 can each correspond to a memory cell of a NVM array in an in-memory computing (IMC) or compute-in-memory (CIM) device. Memory cell regions 652 can be disposed in a row direction 658 (e.g., parallel to word lines and essentially perpendicular to bit lines). As shown, a row of memory cell regions 652 can be formed within second region 654. Such an arrangement can enable a substrate for a row of memory cells to be driven to program/erase bias voltages, without having to drive other rows. This can advantageously enable erasing and programming of memory cell rows with little or no risk of disturbing memory cells outside of the row being programmed.

FIG. 7A is a block diagram showing an IMC array adopting a one-cell per weight configuration according to embodiments of the present disclosure. In one embodiment, IMC array 700 is a m*n NVM array wherein each NVM cell 708 stores one of a plurality of weight values for IMC or MAC operation. As best shown in FIG. 7A, IMC array 700 adopts a similar layout and connection as NVM cell array 102 of FIG. 3 that has m*columns and n*rows of NVM cells 708. NVM cells 708 of the same column are coupled to the same BL (1 to m), whereas NVM cells 708 of the same row are coupled to the same SL (1 to n) and word lines (1 to n). In one embodiment, NVM cells 708 are two-transistor (2T) cells resembling NVM cell 410D in FIG. 4D, having one SONOS transistor 710 and one select transistor 712. SONOS transistor 710 and select transistor 712 are coupled to control gate lines (CGLs) and select gate lines (SGLs) respectively at its gate. It will be the understanding that the 2T SONOS memory cells shown in FIG. 7A are merely an example of NVM cells 708 in IMC array 700. One having ordinary skill in the art would understand other NVM cells, such as those previously discussed in FIGS. 4A to 4E, could be adopted in IMC array 700.

In one embodiment, through signals/voltages received through SGLs and CGLs, a whole row of NVM cells 708 may be selected for a MAC operation by enabling a current path between corresponding BLs and SLs. For example, when row 1 is selected, a current path, within each of NVM cells 708-(1,1 to m,1), are enabled between SL1 and BL (1 to m) respectively. In one embodiment, analog weight values that are stored in SONOS transistors 710 may represent a positive, zero, or negative weight value (W) for the IMC operation. In embodiments, a row of NVM cells, for example NVM cells 708-(1,1 to m,1) may store a set of weight values, also known as a kernel 702-1 for MAC operation. According to system design and other factors, one kernel 702 may include an entire row of NVM cells 708 or a portion of the row. In another embodiment, one row of NVM cells 708 may include more than one kernels 702.

As best shown in FIG. 7A, BLs (1 to m) are coupled to BL driver 704. In one embodiment, BL driver 704 may drive, bias, or otherwise provide a variable analog voltage to each BL (1 to m) individually that is proportional to or representing input values (IN-1 to -m), wherein IN-1 to -m may represent positive, zero, or negative input values for the MAC operation. Alternatively, input values may be digital values wherein BLs can be driven between two different voltages (i.e., input terms can be binary values) and MAC operation may be conducted bit by bit of input values. The overall MAC operation result may be an accumulation or summation of scaled MAC operation results of every bit of input values. Other arithmetic processes may also be adopted according to ordinary skill in the art to calculate the overall MAC operation result with digital input values. In one embodiment, output current or cell current (Ic) of one NVM cell 708 is proportional to or represents (weight value stored*input value). As an example, row 1 or kernel 702-1 includes NVM cells 708-(1,1 to m, 1) and each cell therein stores respective weight values W-1,1 to W-m,1, wherein weight values may represent positive, zero, or negative values. When row 1 is selected, Ic of each NVM cell 708-1, 1 to m, 1 may be collected and accumulated along SL1. The SL output (current or voltage) 706-1 of SL1 may be proportional and represent the result of MAC operation of:

Σ_{x=1 to m}Wx,1*INx (1)

And in general, SL outputs 706 (1 to n) may each represent the MAC operation result of:

$${\sum }_{{x = 1 to m}_{y = 1 to n}} Wx , y * INx \qquad ( 2 )$$

In embodiments, SL outputs 706 are coupled to multiplexors such as MUXs 108 and processing element such as integrator and ADC 112 in FIG. 3 to generate the overall MAC operation result of each SL or kernel.

FIG. 7B is a representative block diagram of IMC or inferencing device 750 according to embodiments of the present disclosure. As discussed, in MAC operations, both weight values and input values can be positive, negative, or zero. In order to accommodate four possible scenarios of +ve weight/+ve input, +ve weight/−ve input, −ve weight/+ve input, and −ve weight/−ve input, four IMC arrays 700 can be adopted in IMC device 750. In one embodiment, IMC device 750 may include two +IMC arrays 700-A&C for +ve weights and two −IMC arrays 700-B&D for −ve weights. IMC arrays 700-A&C and 700-B&D may have a similar structure and configurations as IMC array 700 in FIG. 7A. In one embodiment, only positive weight values or zero are stored in +IMC arrays 700-A&C and only negative weight values or zero are stored in −IMC arrays 700-B&D. As an example, considering storing a kernel of five weights W1 to W5 of (1, 2, 0, −5, −10) in row 1 of IMC arrays 700. In the two +IMC arrays 700-A&C, only five positive or zero weights of (1, 2, 0, 0, 0) are programmed in the corresponding NVM cells. Any negative weight values will be written as “0”. Conversely, in the two −IMC arrays 700-B&D, only five negative or zero weights of (0, 0, 0,−5, −10) will be written in the corresponding NVM cells. Any positive weight values will be written as “0”. One of the ways to achieve “0” weight value in a SONOS based cell, such as NVM cell 708, is to fully program and thus raise Vt to a very high level, such that any current path between its corresponding BL and SL is disabled. Ic of such NVM cells will be substantially zero regardless of the operational voltage difference between V_{SL} and V_{BL}.

As best shown in FIG. 7B, one +IMC array 700-A and one-IMC array 700-B may be coupled to and receive the same set of inputs through the same set of BLs. +BL driver 752 may provide or drive only positive or zero input values into the two IMC arrays 700-A and 700-B. In one embodiment, Ic of NVM cells 708 along one SL may therefore have the same polarity. Considering, as an example, the five inputs In-1 to In-5 are (5, −4, −1, 10, −18), +BL driver 752 may only drive positive voltage proportional to the corresponding inputs through the BLs. All negative inputs will be converted to “0”, so the five inputs provided by +BL driver 752 are (5, 0, 0, 10, 0). One of the ways to achieve it is to drive the corresponding BLs to SL voltage (V_{SL}) such that no current will flow through the NVM cell 708, regardless of stored weights therein. In embodiments and as shown in FIG. 7B, +BL driver 752 may be physically disposed between +IMC and −IMC arrays 700-A and 700-B. Other arrangements may also be adopted without deviating from the principle of the present disclosure. Still referring to FIG. 7B, similarly one +IMC array 700-C and one-IMC array 700-D may be coupled to and receive the same set of inputs through the same BLs, such as BL-y. −BL driver 754 may provide or drive only negative or zero input values into the two IMC arrays 700-C and 700-D. Considering the same five inputs of (5, −4, −1, 10, −18), −BL driver 754 may only drive negative voltage proportional to the corresponding inputs through the BLs. All positive inputs will be written as “0”, so the five inputs provided by −BL driver 754 are (0, −4, −1, 0, −18). In one embodiment, Ic of NVM cells 708 along one SL may have the same polarity. In embodiments, −BL driver 754 may be physically disposed between +IMC and −IMC arrays 700-C and 700-D. Other configurations may also be possible. As previously explained, NVM cells 708 of IMC arrays 700A-D, in response to being selected for a MAC operation via WLs, would enable a current path between their respective SLs, such as SLx and BLs, such as BLy. The magnitude of Ic is proportional to or represents (stored weight*input) and accumulated along the SLs. The polarity of Ic is determined by the polarity of input voltages. In one embodiment, all Ic in a single IMC array 700 has the same polarity, or propagates in the same direction.

In embodiments, SL outputs 706 of SLs are coupled to processing element 756 to generate the overall MAC operation result of each SL or kernel. Considering the same example in which the stored weights in row 1 are W1-W5 as (1, 2, 0, −5, −10) and Inputs In-1-In-5 as (5, −4, −1, 10, −18). The overall MAC operation result is:

ΣWi*In−i=(1*5)+(2*−4)+(0*−1)+(−5*10)+(−10*−18)=+127(3)

And it can be achieved by accumulating or summing MAC results of all four IMC arrays 700-(A to D):
IMC array 700-A result=(1*5)+(2*0)+(0*0)+(0*10)+(0*0)=5
IMC array 700-B result=(0*5)+(0*0)+(0*0)+(−5*10)+(−10*0)=−50
IMC array 700-C result=(1*0)+(2*−4)+(0*−1)+(0*0)+(0*−18)=−8
IMC array 700-D result=(0*0)+(0*−4)+(0*−1)+(−5*0)+(−10*−18)=180
Overall MAC operation result=5+(−50)+(−8)+180=+127

In one embodiment, processing element 756 may include MUXs circuitry, integrator circuitry, ADC circuitry, and other logic circuitry to perform arithmetic operations on cumulative Ic received through SL outputs 706. The output of processing element 756 may be analog currents or voltages representing the overall MAC operation results or digital MAC results. Referring to the aforementioned example, processing element 756 receives cumulative Ic from SL1 of all four IMC arrays 700-(A to D), combines the individual MAC results, i.e. 5, −50, −8, and 127 from each IMC array 700-(A to D) respectively, and generates an overall MAC operation result of +127.

In some embodiments, when inputs are digital, BL drivers 752 and 754 drive BLs between two voltage levels in response to a binary bit of input value “1” or “0” and the MAC operation results are generated bit by bit. In some embodiments, NVM cells 752 may store all negative weights the same manner as positive weights, e.g. in SONOS-based cells. The polarity of cumulative Ic and the polarity of the consequential MAC operation result may be reversed at processing element 756. It will be the understanding that having five NVM cells 708 or weights in one kernel or row is merely an example to illustrate operation details of IMC device 750 and should not be construed as limitations.

A kernel or a row of IMC arrays 700-(A to D) may include large numbers of NVM cells 708, some in the hundreds or even thousands. Consequently, the cumulative Ic of the same polarity along any SLs during MAC operations could have a large magnitude that may cause significant voltage V_{SL} drop along SLs.

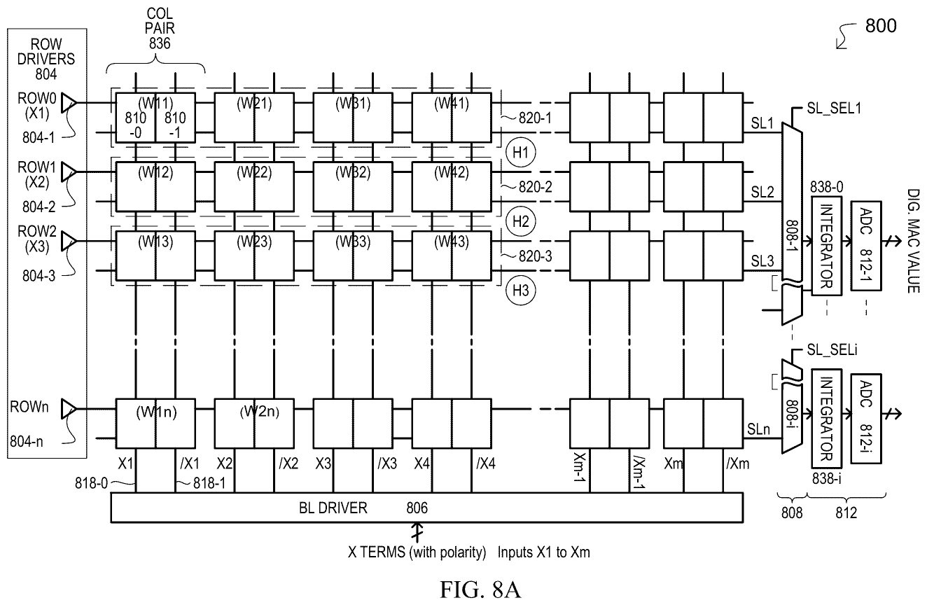

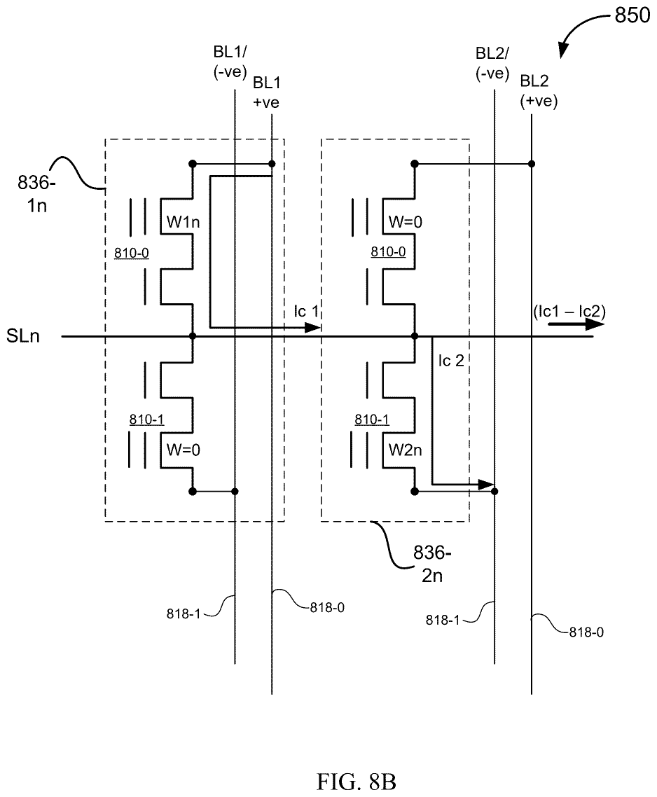

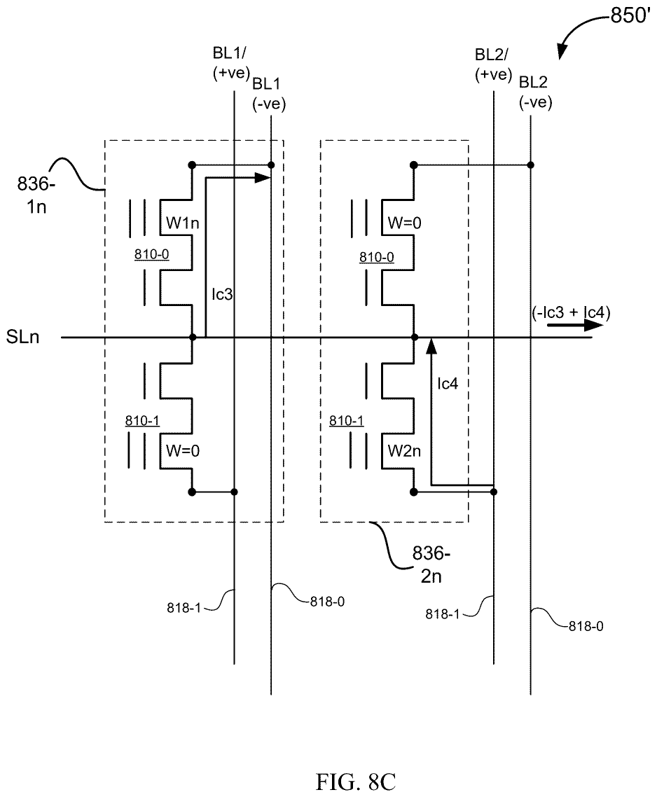

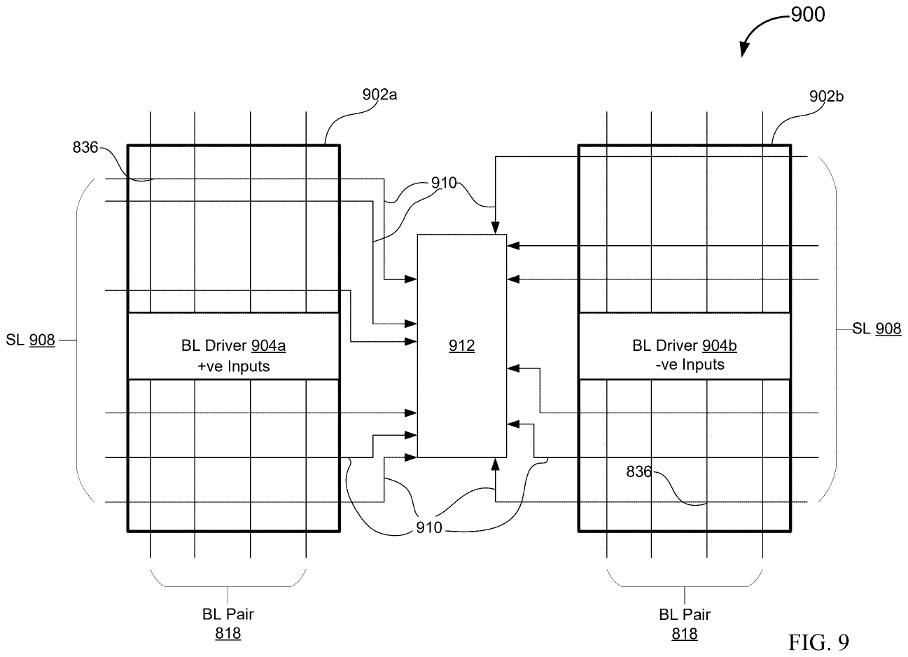

FIG. 8A is a block diagram of IMC device or inferencing device 800 according to another embodiment. In some embodiments, IMC device 800 can be one implementation of that shown in FIG. 3. IMC device 800 can include items like those of FIG. 3, and such like items can operate in a same or similar fashion.

In FIG. 8A, weight values can be zero, positive, and negative; and the same scenario applies for input values. In one embodiment, weight values, depending on its intended polarity, are stored in one of the two adjacent memory cells (shown as 810-0/1) of a column pair or one IMC unit (one shown as 836), in a two cells per weight configuration. For example, memory cell 810-0 can store weight W11 if it is a positive weight, while memory cell 810-1 can store weight W11 if it is a negative weight, (or vice versa). In one embodiment, the memory cell 810-0 or -1 will store a “0” weight value if it is not used to store a weight, e.g. weight W11. If weight W11 is zero, both memory cells 810-0/1 will be programmed to “0”.

According to embodiments, IMC device 800 can store sets of weight values in rows. In addition, weight values can be programmable by rows. By storing weight value sets in rows, embodiments can update weight value sets faster and with less disturb possibilities as compared to conventional devices. Rather that program multiple rows to update one set of weight values, embodiments can program a single row to program a set of weight values or a kernel for MAC operations.

Bit line driver circuits 806 can drive bit lines of a column pair 836 between different voltages. Such a feature can enable input values to have a polarity (+ or −). In some embodiments, one bit line (BL) 818-0 can be driven to a first voltage of a polarity while the other bit line 818-1 is driven to a second voltage of an opposite polarity. In one embodiment, for digital inputs, the magnitude of the first and second voltage is the same and source lines (SLs) are biased to an approximate zero voltage.

In operation, sets of rows can be connected to MUXs 808-1 to 808-i with corresponding source lines SL1 to SLn. Each MUX (808-1 to 808-i) can connect a source line (SL1 to SLn) to ADC circuits in response to select signals SL_SEL-1 to -i. An analog current on the selected source line (SL1 to SLn) can be integrated by a corresponding integrator 838-1 to -i. The integrated charge can be converted into a digital value (DIG. MAC VALUE) by a corresponding ADC circuit 812-1 to -i.

In some embodiments, memory cells can be longer in the column direction than in the row direction. In a conventional device, MUXs can have inputs connected to columns, and extend in the row direction. In contrast, according to embodiments, MUXs can have inputs connected to rows and extend in the column direction. As a result, MUXs can have more area per input than a conventional device.

FIG. 8A shows kernels (weights sets) 820-1 to 820-3 arranged into rows. Kernel 820-0 includes column pairs 836 or memory cells 810-0 and -1 that store weights W11, W21, W31 and W41. With the applications of input values X1-X4, a current can be generated on a source line SL1 corresponding to a MAC result (X1*W11+X2*W21+X3*W31+X4*W41), which can be a summation operation for a neuron (H1). Kernels 820-1/2 provide similar results on source lines SL1 and SL2, respectively. Such an arrangement can enable kernels to be updated with single row programming operations. This is in contrast to conventional approaches that store kernels a column direction, requiring the programming of multiple rows to update a kernel, introducing the possibility of disturbing the states of other memory cells, as well as increasing a wear rate for the memory cell array.

FIGS. 8B and 8C are schematic diagrams showing the application of positive and negative input values to a NVM cell pair or column pair according to an embodiment of the present disclosure. FIG. 8B shows a portion 850 of IMC device 800 including adjacent column pairs 836-1n and 836-2n in row n, respectively in IMC column 1 and 2, coupled to SLn and BL pairs or bundles-1 and -2, respectively. In one embodiment, memory cells 810-0 and 810-1 are SONOS based NVM cells, resembling memory cells 410D as best shown in FIG. 4D. Referring to FIG. 8B, one difference from the embodiment shown in FIG. 8A is that memory cells 810-0 and -1 of the same column pair 836 are disposed in the same column of NVM cells and SLn is coupled to the select transistors of the NVM cells. This particular embodiment will help shortening the SL lengths despite having two memory cells 810-0 and -1 in each column pair 836. As best shown in FIG. 8B, memory cells 810-0 of column pairs 836 are coupled to positive BLs 818-0 and memory cells 810-1 are coupled to negative BLs/818-1. It would be the understanding that other multi-level NVM cells, such as the ones shown and described in FIGS. 4A to 4E, and others may also be included in similar ways in IMC device 800 for MAC operations. In one embodiment, as an example, weight W1n has a positive weight value stored in memory cell 810-0 of column pair 836-1n and W2n has a negative weight value stored in memory cell 810-1 of column pair 836-2n. BL pairs-1 and 2 are coupled to BL driver 806 and SLn is coupled to SL_SEL 808-1 to -i as best shown in FIG. 8A. A zero weight value is stored in memory cell 810-1 of column pair 836-1n and memory cell 810-0 of column pair 836-2n. One of the ways to store a zero weight value in memory cells is to fully program and raise the threshold voltage to a very high level such that current paths within the memory cells are disabled, regardless of V_{BL} and V_{SL}.

An example of operation voltages of SLs and BLs are as follows:

TABLE 1.1
Operation voltages of Positive inputs

| V_{SL} | V_{BL}1 | V_{BL}1/ | V_{BL}2 | V_{BL}2/ |
|---|---|---|---|---|
| 0 V | +ve voltage, | −ve voltage, | +ve voltage, | −ve voltage, |
| | e.g. 100 mV | e.g. −100 mV | e.g. 100 mV | e.g. −100 mV |

Table 1.1 illustrates operation voltages driven to BL, BL/-1&2 when inputs of MAC operations are positive values (i.e. both X1 and X2 are positive). When inputs are zero, V_{BL} will be driven to V_{SL}, in this case 0 V, to ensure approximately zero Ic, regardless of the stored weight values. In some embodiments, BL pairs are driven to a voltage of the same magnitude but opposite polarities, such as +/−100 mV. Referring to FIG. 8A, row n of IMC device 800 is selected for a MAC operation through its WLn (not shown), or other methods. In memory cell 810-0 of column pair 836-1n, since there is a difference between V_{BL}1 and V_{SL}, e.g. (100 mV-0 mV), Ic1 with a magnitude equals to or represents input X1*W1n will flow towards SLn. No or approximate zero Ic will flow through memory cell 810-1 of column pair 836-1n because it is programmed with a “0” weight that disables the current path therewithin. No or approximate zero Ic will flow through memory cell 810-0 of column pair 836-2n because it is programmed with a “0” weight that also disables the current path therewithin. Similarly, in memory cell 810-1 of column pair 836-2n, since there is a difference between V_{BL}2/and V_{SL}, e.g. −100 mV, Ic2 with a magnitude equals to or represents input X2*W2n will flow away from SLn. Along SLn, Ic from column pairs storing positive weights, e.g. 836-1n and Ic from column pairs storing negative weights, e.g. 836-2n, cancel one another, at least partially. As a result, the cumulative Ic (e.g. Ic1-Ic2) is smaller and thus undesirable V_{SL} drop as previously mentioned in FIG. 7B along any SLs will be reduced. It will be the understanding that local cancellation of Ic is not limited to adjacent column pairs, such as column pairs 836-1n and −2n. Positive Ic from any column pairs will be locally canceled by negative Ic from any column pairs coupled to the same SL during MAC operations, and vice versa.

In one alternative embodiment, to avoid having negative BL voltages (V_{BL}S) in any BLs, VBLs are shifted towards positive voltages, as illustrated in Table 1.2.

An example of operation only positive voltages of SLs and BLs are as follows:

TABLE 1.2
Operation Voltages of Positive Inputs

| V_{SL} | V_{BL}1 | V_{BL}1/ | V_{BL}2 | V_{BL}2/ |
|---|---|---|---|---|
| +ve voltage | +ve voltage, | +ve voltage, | +ve voltage, | +ve voltage, |
| e.g. 300 mV | e.g. 400 mV | e.g. 200 mV | e.g. 400 mV | e.g. 200 mV |

In one embodiment, V_{SL} is operable to be a positive voltage with its magnitude between the two BLs (i.e. BLx 818-0 and BLx/818-1). As illustrated in the example in Table 1.2, operation voltage differences between V_{SL} and respectively V_{BL}x and V_{BL}/x are the same (e.g. 100 mV), such that the Ic generated based on + or − weight values will have approximately the same magnitude and opposite polarities (direction of Ic).

Referring to FIG. 8C, the same column pairs 836-1n and -2n are shown storing positive weight W1n and negative weight W2n, respectively. The difference between the embodiment 850 shown in FIG. 8B and the present embodiment 850′ is that negative inputs (i.e. X1 and X2 are both negative) are provided to the column pairs 836-1n and -2n.

An example of operation voltages of SLs and BLs in the embodiment 850′ of FIG. 8B are as follow:

TABLE 2.1
Operation voltages of Negative inputs

| V_{SL} | V_{BL}1 | V_{BL}1/ | V_{BL}2 | V_{BL}2/ |
|---|---|---|---|---|
| 0 V | −ve voltage, | +ve voltage, | −ve voltage, | +ve voltage, |
| | e.g. −100 mV | e.g. 100 mV | e.g. −100 mV | e.g. 100 mV |

Table 2.1 illustrates operation voltages driven to BL, BL/-1&2 when inputs of MAC operations are negative values. When inputs are zero, V_{BL} and V_{BL}/will both be driven to V_{SL}, in this case 0 V, to ensure approximately zero Ic, regardless of the stored weight values. In embodiments, BL pairs are driven to a voltage of the same magnitude but opposite polarities, such as +/−100 mV. During MAC operations of the selected row n, in column pair 852-1n, Ic3 having a magnitude that is equal to or represents input X1*weight W1n will flow away from SLn due to the negative V_{BL}1. Similarly, in column pair 852-2n, Ic4 having a magnitude that is equal to or represents input X2*weight W2n will flow towards SLn due to the positive V_{BL}2/. As a result, Ic3 and Ic4 locally cancel, at least partially, of one another and other cumulative Ic along the same SL.

In embodiments, V_{BL} and V_{BL}/are voltages of analog nature having a magnitude representing or in proportion to a magnitude of corresponding inputs X of the MAC operations. The resulting Ic of individual column pairs or memory cells represents the product of input X*weight W. In some embodiments, it may not be practical to provide a different voltage of various magnitudes or polarities to each BL pair 818, especially if the quantity of varieties of inputs is large. In other embodiments, as best shown in FIGS. 8B and 8C, all BL pairs 818 are driven to the same V_{BL} and V_{BL}/having the same magnitude (e.g. 100 mV) when inputs X are digital bits. As an example, considering input X1=5. It will be converted to its equivalent binary value of “101” and the MAC operation will be performed bit by bit, i.e. 3 times or cycles. During the 1^{st} MAC operation cycle, input X1 is 1 and BL1 is driven to 100 mV, BL1/to −100 mV. During 2^{nd} MAC operation cycle, input X1 is 0 and both BL1 and BL/are driven to 0 V or V_{SL}. During the 3^{rd} MAC operation cycle, input X1 is again 1. BL1 is driven to 100 mV and BL1/to −100 mV. Cumulative Ic of the MAC operation cycle of each bit of input X1 will be scaled according to the significance of the input bit and summed together accordingly to generate the final MAC result. In embodiments, the scaling and summation of Ic per bit of input X may be performed in integrator 838 as best shown in FIG. 8A, or other logic devices known in the art.

Similar to positive inputs, in one alternative embodiment, to avoid having negative BL voltages (V_{BL}S) in any BLs, VBLs are shifted towards positive voltages, as illustrated in Table 2.2.

An example of operation only positive voltages of SLs and BLs are as follows:

TABLE 2.2
Operation Voltages of Negative Inputs

| V_{SL} | V_{BL}1 | V_{BL}1/ | V_{BL}2 | V_{BL}2/ |
|---|---|---|---|---|
| +ve voltage | +ve voltage, | +ve voltage, | +ve voltage, | +ve voltage, |
| e.g. 300 mV | e.g. 200 mV | e.g. 400 mV | e.g. 200 mV | e.g. 400 mV |

In one embodiment, V_{SL} is operable to be a positive voltage with its magnitude between the two BLs (i.e. BLx 818-1 and BLx/818-0). As illustrated in the example in Table 2.2, operation voltage differences between V_{SL} and respectively V_{BL}x and V_{BL}x/are the same (e.g. 100 mV), such that the Ic generated based on + or − weight values will have approximately the same magnitude and opposite polarities (direction of Ic).

FIG. 9 is a representative block diagram of IMC device or inferencing device 900 having the two cells per weight configuration according to the present disclosure. In some embodiments, IMC device 900 can be one implementation of that shown in FIGS. 3 and 8A. IMC device 900 can include items like those of FIGS. 3 and 8A, and such like items can operate in a same or similar fashion or perform similar functions.

Referring to FIG. 9, IMC device 900 may have two identical or similar IMC arrays 902a and 902b adopting a two cells per weight configuration, which may have similar structures and configuration as IMC device 800, as best shown in FIG. 8A. In IMC arrays 902, there may be m*columns and n*rows of column pairs or IMC units 836. In one embodiment, each column pair 836 may include two SONOS based memory cells 810-0 and -1 coupled to the same SL 908, such as column pair 836-1n and can be operated similarly, as best shown in FIG. 8B. It would be the understanding that other multi-level NVM cells, such as those shown and described in FIGS. 4A to 4E, and others may also be included in similar ways in IMC device 900 for MAC operations. In FIG. 9, only a few BL pairs 818 and SLs 908 are shown. One having ordinary skill in the art would appreciate IMC arrays 902 may have any numbers of BL pairs 818, SLs 908, WLs and WLNVs (not shown). In each column pair 836, positive weight, such as W1n in FIG. 8B, is stored in memory cell 810-0 whereas negative weight, such as W2n in FIG. 8B, is stored in memory cell 810-1. In one embodiment, the same weights are stored in both IMC arrays 902a and 902b, and each weight is stored in the correspondingly same location/address of each array 902.

BL drivers 904a and 904b, that are coupled to and configured to receive inputs X, may be positioned at one end (top or bottom) of IMC arrays 902a and 902b, similar to the configuration shown in FIG. 8A. As best shown in FIG. 9, BL drivers 904a and 904b are coupled and positioned in the middle of respective IMC arrays 902a and 902b. This configuration may help reduce BLs length (breaking each BL into two halves), resulting in much less V_{BL} drop along BL pairs 818. In one embodiment, in response to receiving an input set, e.g. X1-Xm, wherein individual inputs can be positive, negative, or zero, BL driver 904a coupled to IMC array 902a can provide or drive BL pairs 818 in IMC array 902a to positive V_{BL} that are proportional or representing inputs X1 to Xm that are positive, e.g. Table 1.1. Any negative inputs or inputs with 0 value will be biased to V_{SL} or OV, or other pre-determined voltages that does not trigger or cause any Ic. As previously explained in FIG. 8B, positive V_{BL} in response to receiving an input set, e.g. X1-Xm, wherein individual inputs can be positive, negative, or zero, BL driver 904a can provide or drive BL 818-0 of BL pairs 818 in IMC array 902a to positive V_{BL} that are proportional or representing only inputs X1 to Xm that are positive. Alternatively, when inputs X1 to Xm are digital values, V_{BL} will be biased to a fixed positive voltage, e.g. 100 mV and V_{BL}/to a fixed negative voltage, e.g. −100 mV, to represent a “1” of input bit (See Tables 1.1 and 1.2). Any negative inputs or inputs with “0” value will be biased to V_{SL} or 0 V, or other pre-determined voltages that does not trigger any Ic.

In IMC array 902b, in response to receiving the same input set, e.g. X1-Xm, BL driver 904b coupled to IMC array 902b can provide or drive BLs 810-0 of BL pairs 818 in IMC array 902b to negative V_{BL} that are proportional or representing inputs X1 to Xm that are negative. Any positive inputs or inputs with “0” value will be biased to V_{SL} or 0 V, or other pre-determined voltages. In embodiments that inputs X1 to Xm are digital values, V_{BL} of BLs 818-0 will be biased to a fixed negative voltage, e.g. −100 mV and VBI/of BLs 818-1 to a fixed positive voltage, e.g. 100 mV, to represent a “1” of input bit (See Tables 2.1 and 2.2). Any positive inputs or inputs with 0 value will be biased to V_{SL} or 0 V, or other pre-determined voltages that does not trigger any Ic. In one embodiment, the combination or summation of MAC results from IMC array 902a (+ve inputs*weights) and IMC array 902b (−ve inputs*weights) may generate the overall MAC results.

When one or more rows of IMC arrays 902a and 902b are selected for a MAC operation via their corresponding WLs or WLNVs (not shown in FIG. 9), Ic will be generated out of column pairs 836 along the selected rows. As previously explained in FIGS. 8B and 8C, regardless of the polarities of inputs, Ic from column pairs 836 storing positive weights will be canceled locally and at least partially by Ic from column pairs 836 storing negative weights. As a result, magnitude of SL outputs 910 cumulated along any SLs 908 may be reduced (comparing to only cumulating exclusively positive or negative Ic).

Similar to embodiments disclosed in FIGS. 3 and 7B, SL outputs 910 are coupled to processing unit or element 912 wherein arithmetic operations, such as adding, subtracting, scaling, etc., will be performed on individual SL outputs 910 to generate the overall MAC operation results. In embodiments, processing unit 912, may include MUXs circuitry, integrator circuitry, ADCs, scaling circuitry, and other logic circuitry known in the art.

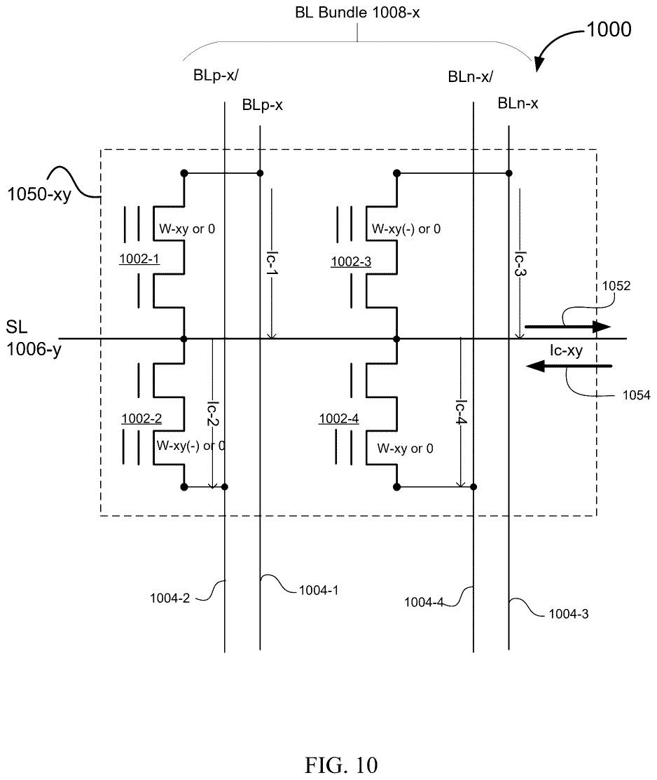

FIG. 10 is a representative diagram showing a four cells per weight IMC unit of an IMC array or device 1000 according to one embodiment of the present disclosure. IMC unit 1050 may be used to store both positive, negative, and zero analog weight values for MAC operations. As best shown in FIG. 10, one IMC unit 1050-xy may include four similar or identical NVM cells or cells 1002-1 to -4, arranged in a 2*2 configuration. In one embodiment, NVM cells or cells 1002 may be 2T SONOS based cells, as best shown in FIG. 4D, or other multi-level NVM cells described in FIGS. 4A to 4E. IMC units 1050 of the same column are coupled through BL bundle 1004 through the memory element or transistor; and each BL bundle 1008 may include four individual BLs 1004-1 to -4. IMC units 1050 of the same row are coupled to SL 1006 through respective select transistors for Ic output and two sets of WLs or WLNWs (not shown in FIG. 10) for row selection. As an example, the IMC unit 1050-xy shown in FIG. 10 is positioned in column x and row y of IMC array 1000.

Each IMC unit 1050, such as IMC unit 1050-xy, stores one weight value which can be positive, negative, or zero for MAC operations. Referring to FIG. 10, when the stored weight W-xy is positive, it is stored in the upper left cell 1002-1 and the lower right cell 1002-4 in duplication. When W-xy is negative, or as shown as W-xy (−), it is stored in the upper right cell 1002-3 and the lower left cell 1002-2 in duplication. In both scenarios, NVM cells 1002 that do not store the weight value will be programmed a weight value of “0”. Each BL bundle 1008 includes four BLs 1004, viz. BLp 1004-1, BLp/1004-2, BLn 1004-3, and BLn/1004-4. As shown in FIG. 10, the upper left and right cells 1002-1 and -3 are coupled to BLp 1004-1 and BLn 1004-3, respectively. The lower left and right cells 1002-2 and -4 are coupled to BLp/1004-2 and BLn/1004-4, respectively. In embodiments, locations of the four cells 1002 within IMC unit 1050 may be interchangeable as long as their respective coupling to the same BLs within the same BL bundle is maintained. In one embodiment, in response to one input-x, four individual V_{BL}S will drive or be provided to all four BLs 1004-1 to -4 in one BL bundle 1006-x.

Similar to IMC device in FIGS. 3, 7B, and 9, all four BLs 1004-1 to -4 in BL bundles 1006 are coupled to and receive individual BL voltages (V_{BL}S) from BL driver(s) (not shown) that provides V_{BL} in response to input values of MAC operations. In one embodiment, SLs 1006 receive V_{SL} from SL driver (not shown) and row(s) of IMC units are selected via its corresponding WLs or WLNVs (not shown) for operations, such as MAC operations. As an example, input-x is digital input provided to IMC unit 1050-xy for MAC operations. The operation voltages of IMC unit 1050-xy are as follow:

TABLE 3.1
Operation voltage examples of four cells per weight IMC units.

| | Input | +ve Input | −ve Input |
|---|---|---|---|
| | (bit) = “0” | (bit) = “1” | (bit) = −“1” |
| BLp | 0 V | +ve voltage, | 0 V |
| | | e.g. 100 mV | |
| BLp/ | 0 V | −ve voltage, | 0 V |
| | | e.g. −100 mV | |
| BLn | 0 V | 0 V | +ve voltage, |
| | | | e.g. 100 mV |
| BLn/ | 0 V | 0 V | −ve voltage, |
| | | | e.g. −100 mV |
| SL | 0 V | 0 V | 0 V |

In general, SLs 1006 are biased to 0 V, or other predetermined voltages. BLs 1008 are biased either to 0 V, or a voltage of equal magnitude in one of the two polarities, such as +/−100 mV. If the bit of input-x (regardless of its polarity) is “0”, all V_{BL}S and V_{SL} are biased to 0 V, or the same voltage, such that no Ic will be generated in any of cells 1002-1 to -4, regardless of the stored weight W-xy or W-xy (−).

In an example that weight W-xy is positive, the weight value is stored in cells 1002-1 and -4 in duplication, whereas cells 1002-3 and -2 store a zero value. If W-xy(−) is negative, the weight value is stored in cells 1002-3 and -2, whereas cells 1002-1 and -4 store a zero value. In response to a positive input-x and an input bit of “1”, in cell 1002-1, positive cell current Ic-1 representing (input bit*weight value W-xy) will flow from BLp-x 1004-1 towards SL 1006-y. Ic-1 will eventually be outputted from cell 1050-xy as positive SL output 1052. There is no Ic generated in the other three cells, viz. 1002-2 to -4 because either one or both of the weight stored therein and V_{BL}S coupled to BL 1004-2 to -4 are zero. When both W-xy (−) and Input-x are negative, only cell 1002-3 will generate a positive cell current Ic-3 representing the magnitude of (input bit*weight value W-xy (−)) flowing from BLn (100 mV) to SL 1006-y (0 V). Ic-3 will also be eventually outputted from cell 1050-xy as positive SL output 1052 while there will be no Ic generated from the other three cells 1002-1, -2, and -4. When W-xy is positive and Input-x is negative, in cell 1002-4, cell current Ic-4 representing the magnitude of (input bit*weight W-xy) will be generated to flow from SL 1006-y (0 V) to BLn-x/(−100 mV). Ic-4 will also be eventually outputted from cell 1050-xy as negative SL output 1054 while there will be no Ic generated from the other three cells 1002-1, -2, and -3. In the fourth scenario, when W-xy is negative and Input-x is positive, in cell 1002-2, cell current Ic-2 representing the magnitude of (input bit*negative weight W-xy (−)) will be generated to flow from SL 1006-y (0 V) to BLp-x/(−100 mV). Ic-2 will also eventually be outputted from cell 1050-xy as negative SL output 1054 while there will be no Ic generated from the other three cells 1002-1, -3, and -4. In various embodiments, depending on one of the four previously described scenarios, a positive Ic-xy 1052 or a negative Ic-xy 1054 will be outputted from IMC unit 1050-xy. Ic from each IMC unit 1050 along the same SL 1006 are cumulative. In embodiments, positive Ic output 1052 from one IMC unit 1050 will be locally canceled, at least partially, by negative Ic output 1054 from another IMC unit along the same SL 1006 or within the same weight kernel, and vice versa.

Similar to the two cells per weight configuration as illustrated in Tables 1.2 and 2.2, to avoid having negative BL voltages (V_{BL}S) in any BLs 1004-1 to -4, V_{SL} and V_{BL}S are shifted towards positive voltages, as illustrated in Table 3.2.

The operation voltages of IMC unit 1050-xy are as follow:

TABLE 3.2
Only Positive Operation Voltage examples
of Four cells per weight IMC units.

| | Input | +ve Input | −ve Input |
|---|---|---|---|
| | (bit) = “0” | (bit) = “1” | (bit) = −“1” |
| BLp | 300 mV | +ve voltage, | 300 mV |
| | | e.g. 400 mV | |
| BLp/ | 300 mV | +ve voltage, | 300 mV |
| | | e.g. 200 mV | |
| BLn | 300 mV | 300 mV | +ve voltage, |
| | | | e.g. 400 mV |
| BLn/ | 300 mV | 300 mV | +ve voltage, |
| | | | e.g. 200 mV |
| SL | 300 mV | 300 mV | 300 mV |

In one embodiment, V_{SL} is operable to be a positive voltage with its magnitude between the BLs (i.e. BLp-x, BLp/-x, BLn-x, and BLn/-x 1004-1 to -4). As illustrated in the example in Table 3.2, operation voltage differences between V_{SL} and respectively V_{BL}x and V_{BL}/x are the same (e.g. 100 mV), such that the Ic generated based on + or − weight values and + or − input binary bits will yield approximately the same magnitude and opposite polarities (direction of Ic).

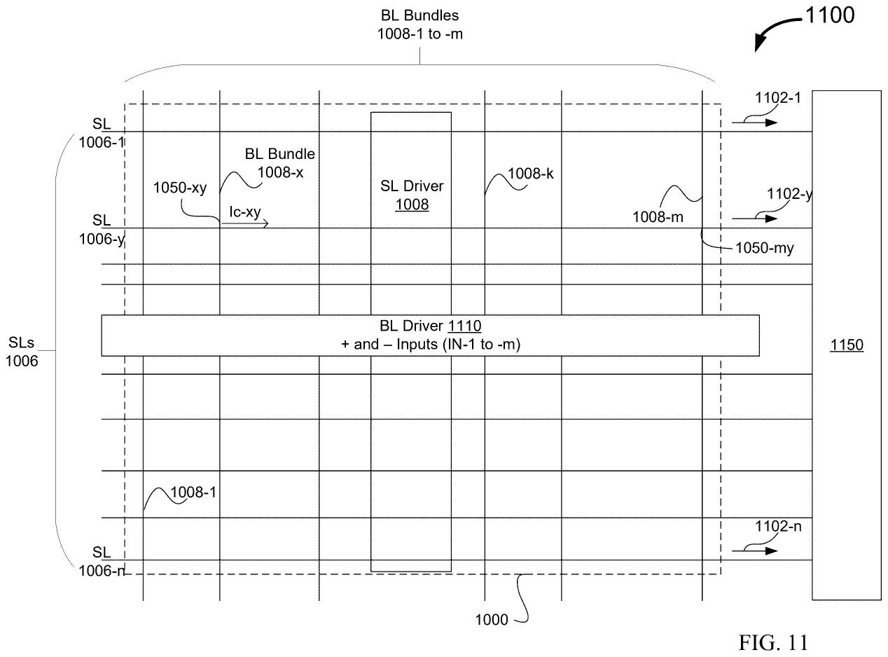

FIG. 11 is a representative schematic diagram showing an embodiment of IMC device or inferencing device 1100 according to the present disclosure. As previously explained, unlike column pairs 836 in IMC device 800 and NVM cells 708 in IMC device 750, each IMC unit 1050 may address all four scenarios of +/−weights and +/−inputs, and zero weights or inputs, it is therefore not required to have more than one NVM or IMC arrays. During operations such as erase and program, row(s) is selected/de-selected using WLs or WLNWs (not shown in FIG. 11) along each row. As best shown in FIG. 11, IMC device 1100 includes IMC array 1000 having m*columns and n*rows of IMC units 1050. Each IMC unit 1050 may include four NVM cells and adopt a layout and connection of IMC unit 1050-xy as best shown in FIG. 10. Analog weights in both polarities and zero for MAC operations can be stored in IMC units 1050 of the same row, in one or more kernels. Each IMC unit 1050, e.g. 1050-xy, is coupled to its corresponding BL bundle 1008-x and SL 1006-y. In one embodiment, each BL bundle 1008 includes four individual BLs 1004-1 to -4, and each of them is coupled to and provides different V_{BL}S to four different terminals of its corresponding IMC unit 1050, as previously explained and best shown in FIG. 10. BL bundles 1008-1 to -m are coupled to BL driver 1110. BL driver 1110 can be disposed at one end of IMC array 1000. In embodiments, it may be positioned in the middle of IMC array 1000, as best shown in FIG. 11, to shorten the length of BL bundles 1008 as well as individual BLs 1004. Large arrays that include a large quantity of IMC units 1050 in one column may require long BL bundles 1008, which may in turn cause undesirable voltage drop, such as (resistance of BL 1004 (RBL)*IBL), along BLs 1004. In one embodiment, a kernel includes an entire row or m*IMC units 1050. In other embodiments, a kernel may just include a portion of a row of IMC units 1050 or there may be multiple kernels in one row. BL driver 1110 receives input IN-1 to -m, which can be 0, +ve, or −ve analog or digital input values. In response, BL driver 1110 may drive BL bundles 1008-1 to -m and each BL 1004 therein to individual V_{BL}S representing the magnitude and polarity of the inputs IN-1 to -m. One example for MAC operation V_{BL}S for digital inputs is illustrated in Table 3 of an earlier section of this document. Consequently, each IMC unit may output Ic (+ve, −ve, or 0) that is equal to or representing (IN (bit)*weight) to their corresponding SL 1006. +ve Ic will locally cancel −ve Ic along SLs 1006, at least partially, and vice versa. In one embodiment, the cumulative SL outputs 1102, i.e. ΣIc along SLs 1006, will not be too large such that it generates undesirable V_{SL} drop (i.e. electrical resistance of SL 1006 (R_{SL})*ΣIc). The voltage drop in either BLs 1004 or SLs 1006 may contribute to undesirable variations in Ic outputs of IMC units 1050, which will affect the accuracy of MAC results adversely.

SLs 1006-1 to -n are coupled to each IMC unit 1050 along the same SL 1006 and SL driver 1008. SL driver 1008 may be positioned at one end of SLs 1006 to provide V_{SL} S to SLs 1006 during various operations, including MAC operations. SL driver 1008 may provide a predetermined V_{SL} or V_{SL} S to SLs 1006, or bias all SLs to 0 V, as per Table 3 during MAC operations. In other embodiments, SL driver 1008 may be disposed between two halves of the same SLs 1006, as best shown in FIG. 11. The shortening SL 1006 halves, and in turn potential reduction of resistance of SL 1006 (R_{SL}), may reduce the voltage drop, such as (R_{SL}*ΣIc), along SLs 1006 during operations. It is especially important for IMC arrays having a long row (SL) with a large quantity of IMC units 1050 in each row.

One end of SLs 1006 with SL outputs 1102 are coupled to processing unit 1150. In one embodiment, similar to processing unit 912 in IMC device 900 shown in FIG. 9, processing unit 1150 is designed and configured to receive SL outputs 1102 and generate the overall MAC operation results that represent ΣIN*Weight. In embodiments, processing unit 1150 may include MUXs circuitry, scaling circuitry, integrator circuitry, ADCs, and other logic circuitry known in the art for scaling of MAC results of digital input bits, multiplexing, and performing arithmetic operations on SL outputs 1102 to generate the overall MAC results.

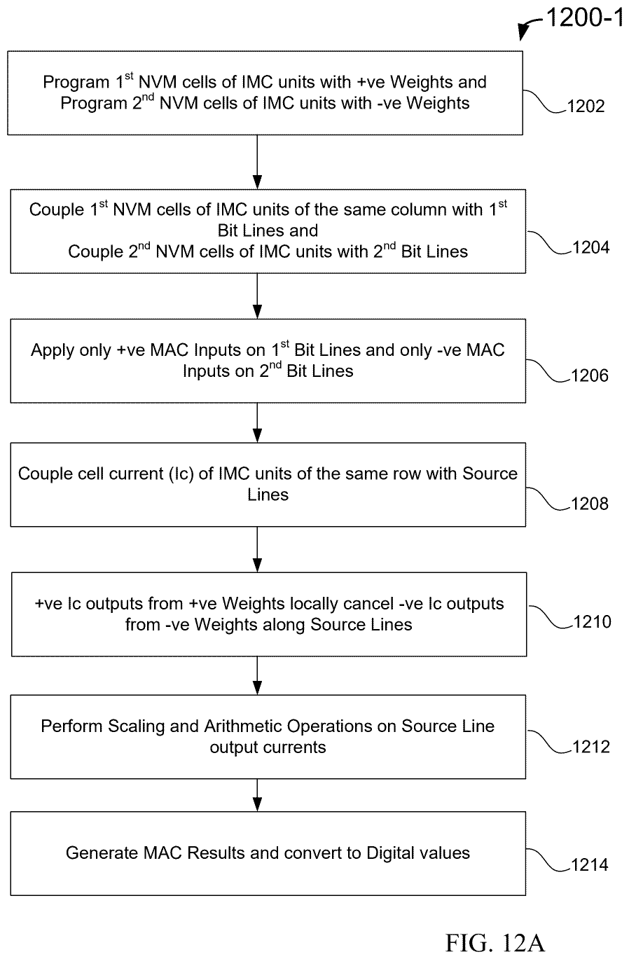

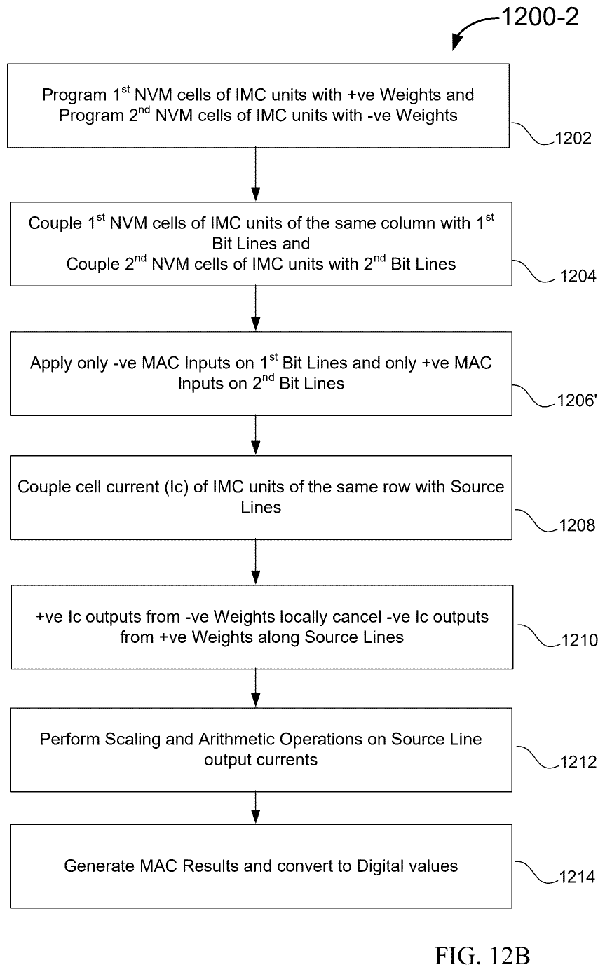

FIG. 12A is a flow diagram of a MAC results generation method 1200-1 with an IMC/inferencing device, such as IMC device 900 in FIG. 9, according to an embodiment of the present disclosure. Method 1200-1 may include populating or programming weight value sets for MAC operations in IMC units in an IMC array having NVM cells, in step 1202. In one embodiment, NVM cells may be trimmed to one of multiple levels of conductance (e.g. 128 levels to represent weight values of −128 to +127). Each weight set is stored in a single row of IMC units, or a kernel. In one embodiment, positive weights may be stored only in the first NVM cells of the IMC units and negative weights only in the second NVM cells, as explained in FIGS. 8B and 8C. The method 1200-1 may also include coupling first NVM cells of the same column with first BLs, and second NVM cells with second BLs, in step 1204. When MAC operation starts, inputs of MAC operations are received in BL driver(s). In response to positive inputs only, BL driver(s) would then drive first BLs in the corresponding columns to a positive voltage and second BLs to a negative voltage, in step 1206. In one embodiment, the magnitude of the positive and negative voltages may be variable and representing the corresponding analog input values. In another embodiment, for digital inputs, the positive and negative voltages may have the same magnitude of opposite polarities. The consequential Ic output of each IMC unit may represent the product of Stored Weight*Input (only positive).

IMC units of the same rows are coupled together in the same SLs, and receive the same SL voltages. When certain rows of IMC units are selected for a MAC operation through their WLs or WLNWs, IMC units will be triggered by BL voltages on both first and second BLs to generate cell currents Ic. Consequently, Ic from IMC units will be outputted to their corresponding SLs, in step 1208. In one embodiment, positive Ic output will be locally canceled, at least partially, by negative Ic output of the same SLs, in step 1210. Cumulative SL current is reduced due to the local cancellation of Ic outputs.

The total Ic output along SLs are then coupled to a processing unit. In embodiments, the processing unit may include MUXs circuitry, integrator circuitry, and ADC circuitry that may perform scaling, arithmetic, multiplexing operations on SL output currents, in step 1212. In one embodiment, the analog result will then be converted to digital values as the overall result of the MAC operations, in step 1214.

The method 1200-1, as best shown in FIG. 12A, would generate a MAC operation result of Σ(weight*+ve input) along SLs of the IMC device. In embodiments that input values are both positive and negative, two identical or similar IMC arrays may be needed. FIG. 12B is a flow chart illustrating a method of MAC results generation when some inputs are negative, according to an embodiment of the present disclosure. Steps 1202 and 1204 in method 1200-2 is the same as steps 1202 and 1204 of method 1200-1, wherein IMC units of rows are populated with both positive and negative MAC weight sets and first/second BLs are coupled to corresponding NVM cells of IMC units of the same columns. In step 1206′, only negative MAC inputs induced BL voltages are provided to first and second BLs. In one embodiment, negative BL voltages are coupled to first BLs and positive BL voltages are coupled to second BLs, in step 1206′. The BL voltage coupling is the exact opposite of step 1206 described in method 1200-1. In one embodiment, the consequential Ic output of each IMC unit along SLs may represent the product of, Stored Weight*Input (only negative).

Consequently, Ic from IMC units will be outputted to their corresponding SLs, in step 1208. In one embodiment, positive Ic output will be locally cancel, at least partially, by negative Ic output from IMC units of the same SLs, in step 1210. Cumulative SL current magnitude is reduced due to the local cancellation of Ic outputs.

The total Ic output along SLs are then coupled to the same processing unit in method 1200-1. The processing unit may perform scaling, arithmetic, multiplexing operations on SL output currents, in step 1212. In addition, the processing unit may combine the SL output currents for positive inputs as described in method 1200-1 and for negative inputs to generate the total SL output currents. In one embodiment, the analog result of the total SL output currents from both IMC arrays will then be converted to digital values as the overall result of the MAC operations, in step 1214.

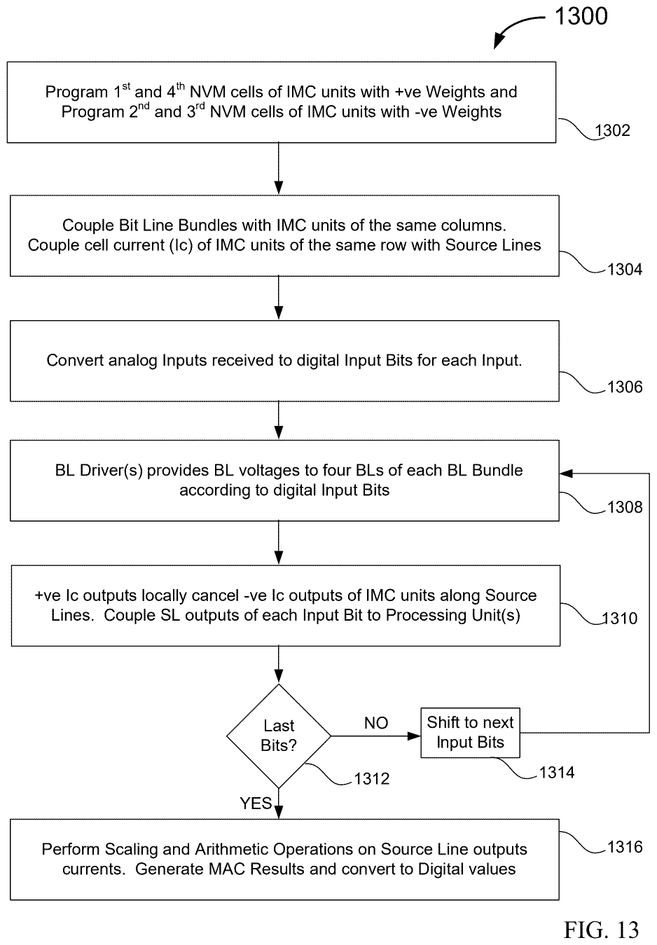

FIG. 13 is a flow diagram of a MAC results generation method 1300 with an IMC device, such as IMC device 1100 in FIG. 11, according to an embodiment of the present disclosure. In one embodiment, each IMC unit in the IMC device has four NVM cells, i.e. four cells per weight, to store one weight value for MAC operations. In one embodiment, all positive weights of a weight set are stored in the first and fourth NVM cells in duplication and negative weights are stored in the second and third NVM cells in duplication of corresponding IMC units in one row, in step 1302. NVM cells that are not used to store either positive or negative weights are programmed to “0”. IMC units of the same columns and rows are coupled to their corresponding BL bundles and SLs respectively, in step 1304. Each BL bundle has four BLs viz. BLp, BLp/, BLn, and BLn/, and each BL is coupled to one NVM cell in the same IMC unit, one of such embodiments is best illustrated in FIG. 10 and its corresponding description. In one embodiment, each NVM cell has its Ic output coupled to its corresponding SL. Inputs of MAC operations are often provided to the IMC device as analog values. In one embodiment, analog inputs are converted to digital input bits, “0” and “1” or “−1” using conventional methods, in step 1306. BL driver(s), in response to each binary bit of inputs, will generate four individual BL voltages (V_{BL}) to each of the four BLs in BL bundles, in step 1308. One example of operation BL and SL voltages are shown and explained in Tables 3.1 or 3.2 of the present document. In embodiments, each IMC unit along the SL will be triggered to generate Ic that is equal to or representing (stored weight*input bit). Positive Ic (both weight and input bit are positive or negative) and negative Ic (only one of the weight or input bit is negative) will locally cancel, at least partially, one another along the SL, in step 1310. Accordingly, the cumulative Ic from each IMC unit along the SL is outputted as SL output current and coupled to a processing unit, also in step 1310.

Next, IMC device will check whether the last processed input bit is the last bit in the inputs, in step 1312. If it is the last bit, method 1300 will progress to generating MAC result step 1316. If it is not the last bit, the process will shift to the next input bit and back to step 1308.

Once all input bits of inputs are processed, the MAC result generation may start, in step 1316. SL output currents from each round will be scaled according to the significance of their corresponding input bits. As an example, input is “5”. It will be converted to 3 input bits “101” and each input bit will cause BL drivers to generate appropriate individual V_{BL}S to each BL. In one embodiment, the Ic triggered by the 1^{st} bit “1” will be scaled 2² times since it is the most significant bit compared to the last (3^{rd} bit) “1”. Scaling of Ic according to the significance of input bits may be accomplished by conventional methods, such as using a capacitor circuitry. Scaled SL outputs of each input bit will then be summed together or undergo other arithmetic operations to generate the total MAC current or analog result, i.e. E stored weight*input. In embodiments, the analog MAC results will then be converted to digital results, using conventional methods.

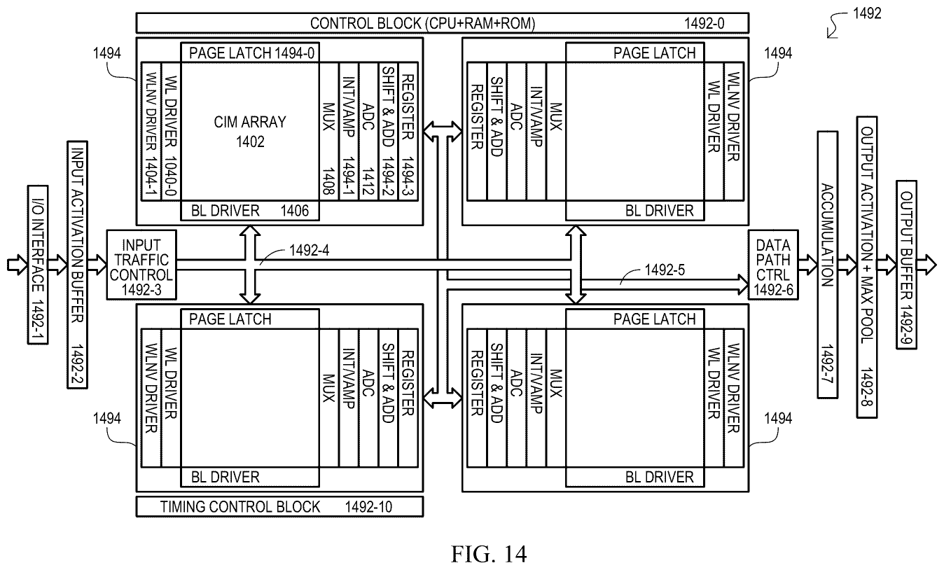

FIG. 14 is a block diagram of an IMC device or system having multiple IMC arrays according to an embodiment of the present disclosure. In one embodiment, IMC device 1492 can include compute in memory (CIM) blocks (four shown as 1494), a control block 1492-0, I/O interface 1492-1, input activation buffer 1492-2, input traffic control 1492-3, an input bus system 1492-4, an output bus system 1492-5, data path control 1492-6, accumulation section 1492-7, output activation section 1492-8, output buffer 1492-9, and timing control block 1492-10. In embodiments, CIM blocks 1494 may have similar architecture and functions as IMC arrays or devices as best shown in FIG. 7B, 9, or 11.

CIM blocks 1494 can include CIM array(s) 1402 including NVM cells such as NVM cells described in FIGS. 4A to 4E, bit line driver 1406, MUXs 1408, word line drivers 1040-0/1, and ADCs 1412. Such items can take the form of any of those described herein or equivalents. In addition, CIM blocks 1494 can include a page latch 1494-0, integrator/amplifier circuits 1494-1, shift/add circuits 1492-2, and block registers 1494-3. Page latch 1494-0 can store a page of data from CIM array 1402. CIM array 1402 can be programmed with non-binary weight data having at least three distinctive levels. In embodiments, CIM array 1402 may adopt a one cell per weight (e.g. FIG. 7A), two cells per weight (e.g. FIG. 9), or four cells per weight (e.g. FIG. 10) architecture as described in earlier sections of this document. While programming the weights in the CIM array 1402, the input weight data or information pertaining to the input weight data can be stored in a page latch 1494-0, which is then used during programming operations. In inference operation, the integrator/amplifier circuits 1494-1 can integrate current values provide by MUXs 1408 and amplify a resulting value prior to ADC conversion.

Shift/add circuits 1492-2 can modify digital MAC results. Block registers 1494-3 can store output values of CIM blocks 1494, for subsequent output from IMC device 1492. In some embodiments, block registers 1494-3 can also store input data to CIM blocks 1494. Thus, output data from one CIM block 1494 can be provided as input data to another CIM block 1494.

A control block 1492-0 can control operations of IMC device 1492. In some embodiments, a control block can include a CPU and corresponding ROM and RAM. I/O interface 1492-1 can receive input data for IMC device 1492. Input activation buffer 1492-2 can store input data, and in some embodiments can selectively enable input data to be applied to CIM arrays, based on predetermined criteria. In some embodiments, input activation buffer 1492-4 can serve as one or more neuron input activation functions. Input traffic control 1492-3 can control which input data are applied to which CIM blocks 1494. Input traffic control 1492-3 can steer input data with any suitable method, including but not limited to, by a destination value accompanying the input data or time division multiplexing. Input bus system 1492-4 can provide a data path for input data to each CIM block 1494. Output bus system 1492-5 can provide a data path for output from each CIM block 1494. Input and output bus systems 1492-4/5 can be parallel buses, serial buses, or a combination of both.

Data path control 1492-6 can selectively pass output data from CIM blocks 1494. Accumulation section 1492-7 can accumulate output values from CIM blocks 1494. Output activation buffer 1492-8 can store output data for IMC device 1492 and perform activation operations (e.g., ReLu, tanh, sigmoid). In some embodiments, output activation buffer 1492-8 can serve as one or more neuron output activation functions. In some embodiments, output activation buffer 1492-8 can perform other operations on output data, including pooling or other aggregation or filtering functions. Output buffer 1492-9 can drive output data on output connections (e.g., on configurable switch fabric). Timing and control block 1492-10 can generate timing and control signal for coordinating operations of IMC device 1492.

Thus, embodiments of in-memory computing device and system using multi-level or analog non-volatile memory cells and operation methods thereof have been described. Although the present disclosure has been described with reference to specific exemplary embodiments, it will be evident that various modifications and changes may be made to these embodiments without departing from the broader spirit and scope of the disclosure. Accordingly, the specification and drawings are to be regarded in an illustrative rather than a restrictive sense.

The Abstract of the Disclosure is provided to comply with 37 C.F.R. § 1.72 (b), requiring an abstract that will allow the reader to quickly ascertain the nature of one or more embodiments of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

Reference in the description to one embodiment or an embodiment means that a particular feature, structure, or characteristic described in connection with the embodiment is included in at least one embodiment of the circuit or method. The appearances of the phrase one embodiment in various places in the specification do not necessarily all refer to the same embodiment.

What is claimed is:

1. A semiconductor device, comprising:
at least one non-volatile memory (NVM) array, wherein each NVM array includes:
in-memory computing (IMC) units arranged in rows and columns, wherein
each IMC unit includes at least two NVM cells configured to store a weight value;
a plurality of bit line (BL) bundles, each BL bundle including at least two BLs coupled to one column of the IMC units to provide a BL voltage set representing an input value, wherein the IMC units of the one column each provides a cell current output varies according to the weight value stored therein and the BL voltage set coupled thereto; and
a plurality of source lines (SLs), each SL coupled with the cell current outputs of one row of the IMC units, wherein positive cell current outputs are canceled, at least partially, by negative cell current outputs of the one row of the IMC units.

2. The semiconductor device of claim 1, wherein the cell current outputs each represents a function of each input value and a corresponding weight value stored by the IMC units of the one row; and cumulative cell current outputs along the each SL represents a multiply-accumulate (MAC) result.

3. The semiconductor device of claim 1, further comprising:
a plurality of word lines (WLs), each WL coupled to a corresponding row of the IMC units, each configured to select the IMC units of the corresponding row for an operation including a multiply-accumulate (MAC) operation.

4. The semiconductor device of claim 1, wherein the weight values are analog weights of a multiply-accumulate (MAC) operation, and each NVM cell includes a multi-level SONOS based memory transistor having a threshold voltage representing the weight value stored therein.

5. The semiconductor device of claim 1, wherein each IMC unit includes two NVM cells and the weight value stored therein has one of zero, positive, or negative value, and wherein:
a positive weight value is stored in a first NVM cell of the each IMC unit;
a negative weight value is stored in a second NVM cell, wherein the first and second NVM cells are coupled to a same SL and first and second BLs of a same BL bundle, respectively.

6. The semiconductor device of claim 5, wherein the BL voltage set coupled to the each IMC unit includes:
a positive BL voltage, in response to the input value being positive, is provided to the first BL; and
a negative BL voltage, in response to the input value being positive, is provided to the second BL.

7. The semiconductor device of claim 5, wherein the BL voltage set coupled to the each IMC unit includes:
a negative BL voltage, in response to the input value being negative, is provided to the first BL; and
a positive BL voltage, in response to the input value being negative, is provided to the second BL.

8. The semiconductor device of claim 1, wherein each IMC unit includes four NVM cells arranged in two adjacent NVM cell columns and the weight value stored therein has one of zero, positive, or negative value, and wherein:
a positive weight value is each stored in first and fourth NVM cells coupled to first and fourth BLs in a same BL bundle, respectively;
a negative weight value is each stored in second and third NVM cells coupled to second and third BL of the same BL bundle, respectively, wherein the first and second NVM cells, and the third and fourth NVM cells, are each arranged in a same NVM cell column respectively.

9. The semiconductor device of claim 8, wherein the BL voltage set coupled to the IMC unit includes:
a positive BL voltage, in response to the input value being positive, is provided to the first BL;
a negative BL voltage, in response to the input value being positive, is provided to the second BL; and
a zero BL voltage, in response to the input value being positive, is provided to the third and fourth BLs.

10. The semiconductor device of claim 8, wherein the BL voltage set coupled to the IMC unit includes:
a positive BL voltage, in response to the input value being negative, is provided to the third BL;
a negative BL voltage, in response to the input value being negative, is provided to the fourth BL; and
a zero BL voltage, in response to the input value being negative, is provided to the first and second BLs.

11. An inferencing device, comprising:
at least one non-volatile memory (NVM) array, wherein each NVM array includes in-memory computing (IMC) units arranged in rows and columns, wherein the IMC unit each includes at least two NVM cells to collectively store a weight value;
a bit line (BL) driver coupled to the each NVM array, wherein the BL driver receives input value sets of multiply-accumulate (MAC) operations and provides BL voltage sets accordingly;
a plurality of bit line (BL) bundles coupled to the BL driver, each BL bundle including at least two BLs coupled to one column of the IMC units to provide the BL voltage set from the BL driver, wherein the IMC units of the one column each provides a cell current output varies according to the weight value stored therein and the BL voltage set coupled thereto;
a plurality of source lines (SLs), each SL coupled with the cell current outputs of one row of the IMC units, wherein positive cell current outputs of the one row of the IMC units are canceled, at least partially, by negative cell current outputs along the each SL; and
a processing element coupled to the plurality of SLs to receive cumulative cell current outputs of each SL, the processing element is configured to generate a MAC result based on cumulative cell current outputs of the each SL.

12. The inferencing device of claim 11 includes one NVM array, wherein each IMC unit includes four NVM cells arranged in two adjacent NVM cell columns and the weight value stored therein has one of zero, positive, or negative value, and wherein:
a positive weight value is each stored in first and fourth NVM cells coupled to first and fourth BLs in a same BL bundle, respectively;
a negative weight value is each stored in second and third NVM cells coupled to second and third BL of the same BL bundle, respectively, wherein the first and second NVM cells and the third and fourth NVM cells are each arranged in a same NVM cell column, respectively; and
a zero weight value is stored in the first, second, third, and fourth NVM cells.

13. The inferencing device of claim 12, wherein the BL voltage set coupled to the IMC unit includes:
a positive BL voltage, in response to the input value being positive, is provided to the first BL;
a negative BL voltage, in response to the input value being positive, is provided to the second BL; and
a zero BL voltage, in response to the input value being positive, is provided to the third and fourth BLs.

14. The inferencing device of claim 12, wherein the BL voltage set coupled to the IMC unit includes:
a positive BL voltage, in response to the input value being negative, is provided to the third BL;
a negative BL voltage, in response to the input value being negative, is provided to the fourth BL; and
a zero BL voltage, in response to the input value being negative, is provided to the first and second BLs.

15. The inferencing device of claim 11, wherein the BL driver is disposed in the middle of the one NVM array and provides same BL voltage sets to two halves of the plurality of BL bundles coupled thereto.

16. The inferencing device of claim 11, wherein the input value sets include digital values in binary bits, and wherein the MAC operations are performed bit by bit until last binary bits of the input value sets are processed.

17. The inferencing device of claim 11, wherein one row of IMC units includes a kernel, wherein the kernel is configured to store a set of weight values to generate the MAC operations with the input value sets.

18. The inferencing device of claim 16, wherein the processing element further comprising:
scaling circuitry configured to scale the MAC result of each binary bit of the input value sets according to significance of the each binary bit;
multiplexers circuitry configured to couple to a different set of SLs;
integrator circuitry configured to integrate scaled MAC results of the binary bits of the input value sets to generate an overall MAC result; and
analog-digital converter (ADC) circuitry configured to covert the overall MAC result into a digital output of the inferencing device.

19. A method of operating an inferencing device, comprising:
storing weight values in in-memory computing (IMC) units each including at least two nonvolatile memory (NVM) cells of an NVM cell array of the inferencing device, the NVM cell array having rows and columns, wherein one row and one column of the IMC units are coupled to a source line and a bit line bundle respectively, wherein weight values can vary between no less than three different values and are one of positive values, negative values, or zero;
for at least one row, generating a multiply-accumulate (MAC) result for the row by applying bit line voltage sets representing input values on bit line bundles wherein input values are one of positive values, negative values, or zero, the MAC result comprising a summation of an analog current that is a function of each input value and a corresponding weight value stored by the IMC units of the row, wherein positive analog current is cancelled at least partially by negative analog current provided by IMC units of the row; and
by operation of at least one multiplexer, connecting one of a plurality of the rows to an analog-to-digital converter (ADC) circuit to convert the summation of the analog current of the row into a digital MAC value.

20. The method of claim 19, wherein each IMC unit include four NVM cells, the method further comprising:
generating, by a bit line driver, the bit line voltage sets each including four individual bit line voltages, each of the bit line voltages provided to one of the four NVM cells respectively, wherein the bit line voltage set causes only one of the four NVM cells of the each IMC unit to provide the analog current from the IMC unit.
